(19) United States
(12) Patent Application Publication
(10) Pub. No.: US 2025/0364035 A1
(43) Pub. Date: Nov. 27, 2025

(54) MEMORY AND MANUFACTURING METHOD THEREOF

(71) Applicant: SwaySure Technology Co., Ltd., Shenzhen (CN)

(72) Inventors: JINGHAO WANG, Shenzhen (CN); Koji Fujisawa, Shenzhen (CN)

(21) Appl. No.: 19/188,243

(22) Filed: Apr. 24, 2025

(30) Foreign Application Priority Data
May 21, 2024 (CN) 202410637496.7

(51) Int. Cl. G11C 11/4096; G11C 5/06; H10B 12/00

(52) U.S. Cl. CPC G11C 11/4096; G11C 5/063; H10B 12/01; H10B 12/20

(57) ABSTRACT

A method for manufacturing the memory includes: providing a semiconductor substrate; preparing at least one storage unit on the semiconductor substrate; the storage unit includes at least one transistor, and each transistor includes a gate electrode, a gate dielectric, a semiconductor channel, an upper electrode and a lower electrode, the semiconductor channel surrounds at least an outer peripheral side of the gate electrode, the gate dielectric is formed between the semiconductor channel and the gate electrode, the upper electrode and the lower electrode are located outside the semiconductor channel and are in contact with the semiconductor channel, and the lower electrode is provided below the upper electrode in an insulating manner; performing an oxidation treatment on a to-be-oxidized region of an effective semiconductor channel in the at least one transistor in the storage unit, to make the to-be-oxidized region form an oxidized channel.

### CROSS-REFERENCE TO RELATED APPLICATIONS

This application claims priority to Chinese Patent Application No. 202410637496.7, filed on May 21, 2024, the entire disclosure of which is hereby incorporated herein by reference.

### TECHNICAL FIELD

The present disclosure belongs to the field of semiconductor technology, and specifically relates to a memory and a manufacturing method thereof.

### BACKGROUND

With the miniaturization of technology nodes, capacitor-less memories becomes a research hotspot. Currently, the structure of capacitor-less memories tends to be a three-dimensional structure. When using the oxidation treatment to improve the defects of the channel in a three-dimensional capacitor-less memory, the entire channel will be oxidized easily. As a result, the resistance of the entire channel will increase, which is not conducive to the improvement of electrical performance.

### SUMMARY

There are provided a memory and a manufacturing method thereof according to embodiments of the present disclosure. The technical solution is as below:

The first aspect of the present disclosure provides a method for manufacturing a memory, which includes:
providing a semiconductor substrate;
preparing at least one storage unit on the semiconductor substrate;
where the storage unit includes at least one transistor, and each transistor includes a gate electrode, a gate dielectric, a semiconductor channel, an upper electrode and a lower electrode, the semiconductor channel surrounds at least an outer peripheral side of the gate electrode, the gate dielectric is formed between the semiconductor channel and the gate electrode, the upper electrode and the lower electrode are located outside the semiconductor channel and are in contact with the semiconductor channel, and the lower electrode is provided below the upper electrode in an insulating manner, and one of the upper electrode and the lower electrode is a source electrode, and another one of the upper electrode and the lower electrode is a drain electrode;
performing an oxidation treatment on a to-be-oxidized region of an effective semiconductor channel in the at least one transistor in the storage unit, to make the to-be-oxidized region form an oxidized channel; and
where the to-be-oxidized region is at least a part of the effective semiconductor channel, and neither the upper electrode nor the lower electrode is in contact with the oxidized channel;
where the effective semiconductor channel is a part of the semiconductor channel located between the upper electrode and the lower electrode.

The second aspect of the present disclosure provides a memory, which includes:
a semiconductor substrate; and
at least one storage unit, formed on the semiconductor substrate.
where the storage unit includes at least one transistor, and each transistor includes a gate electrode, a gate dielectric, a semiconductor channel, an upper electrode and a lower electrode; the semiconductor channel surrounds at least an outer peripheral side of the gate electrode, and the gate dielectric is formed between the semiconductor channel and the gate electrode;
the upper electrode and the lower electrode are located outside the semiconductor channel and are in contact with the semiconductor channel, and the lower electrode is provided below the upper electrode in an insulating manner;
one of the upper electrode and the lower electrode is a source electrode, and another one of the upper electrode and the lower electrode is a drain electrode;
where in the storage unit: a part of the effective semiconductor channel in the at least one transistors is subjected to an oxidation treatment to form an oxidized channel;
the effective semiconductor channel is a part of the semiconductor channel located between the upper electrode and the lower electrode, and neither the upper electrode nor the lower electrode is in contact with the oxidized channel.

### BRIEF DESCRIPTION OF THE DRAWINGS

The accompanying drawings herein are incorporated into the specification and constitute a part of the specification, showing the embodiments conforming to the present disclosure, and are used together with the specification to explain the principles of the present disclosure. Obviously, the accompanying drawings in the following description are only some embodiments of the present disclosure. For those skilled in the art, other drawings can be obtained according to these drawings without creative efforts.

FIG. 1 is a schematic structural view of the structure formed corresponding to step S100 in the method for manufacturing the memory according to the embodiment of the present disclosure.

FIG. 2 is a schematic structural view of the structure formed corresponding to step S102 in the method for manufacturing the memory according to the embodiment of the present disclosure.

FIG. 3 is a schematic structural view of the structure formed corresponding to step S104 in the method for manufacturing the memory according to the embodiment of the present disclosure.

FIG. 4 is a schematic structural view of the structure after the gas channel is formed in the method for manufacturing the memory according to the embodiment of the present disclosure.

FIG. 5 is a schematic structural view of the structure after the oxidized channel is formed by introducing the oxidization gas into the gas channel in the method for manufacturing the memory according to the embodiment of the present disclosure.

FIG. 6 is a schematic structural view of the structure after the filling body is formed by partially filling the gas channel in the method for manufacturing the memory according to the embodiment of the present disclosure.

FIG. 7 is a schematic structural view of the storage unit in the memory including a read transistor and a write transistor according to the embodiment of the present disclosure.

FIG. 8 is a schematic structural view of the structure after only the to-be-oxidized region of the read transistor is oxidized to form the oxidized channel in the method for manufacturing the memory according to the embodiment of the present disclosure.

FIG. 9 is a schematic structural view of the structure after only the to-be-oxidized region of the write transistor is oxidized to form the oxidized channel in the method for manufacturing the memory according to the embodiment of the present disclosure.

FIG. 10 is a schematic structural view of the structure after both the to-be-oxidized regions of the read transistor and the write transistor are oxidized to form the oxidized channels in the method for manufacturing the memory according to the embodiment of the present disclosure.

FIG. 11 is a schematic structural view of the structure after the gas channel is formed corresponding to the method for manufacturing the memory in the first embodiment of the present disclosure.

FIG. 12 is a schematic structural view of the structure after the first oxidized channel and the second oxidized channel are simultaneously formed by introducing the oxidization gas into the gas channel in the method for manufacturing the memory in the first embodiment of the present disclosure.

FIG. 13 is a schematic structural view of the structure after the filling body is formed by completely filling the gas channel in the method for manufacturing the memory in the first embodiment of the present disclosure.

FIG. 14 is a schematic structural view of the structure after the filling body is formed by partially filling the gas channel in the method for manufacturing the memory in the first embodiment of the present disclosure.

FIG. 15 is a schematic structural view of the structure formed corresponding to step S200 in the method for manufacturing the memory according to the embodiment of the present disclosure.

FIGS. 16 and 17 respectively show schematic diagrams of the structure formed corresponding to step S200 in the method for manufacturing the memory from different perspectives according to the embodiment of the present disclosure.

FIG. 18 is a schematic structural view of the structure formed corresponding to step S202 in the method for manufacturing the memory according to the embodiment of the present disclosure.

FIG. 19 is a schematic structural view of the structure corresponding to the formation of the read transistor in the method for manufacturing the memory according to the embodiment of the present disclosure.

FIG. 20 is a schematic structural view of one kind of structure formed corresponding to step S2041 in the method for manufacturing the memory according to the embodiment of the present disclosure.

FIG. 21 is a schematic structural view of another kind of structure formed corresponding to step S2041 in the method for manufacturing the memory according to the embodiment of the present disclosure.

FIG. 22 is a schematic structural view of yet another kind of structure formed corresponding to step S2041 in the method for manufacturing the memory according to the embodiment of the present disclosure.

FIG. 23 is a schematic structural view of one kind of structure formed corresponding to step S206 in the method for manufacturing the memory according to the embodiment of the present disclosure.

FIG. 24 is a schematic structural view of another kind of structure formed corresponding to step S206 in the method for manufacturing the memory according to the embodiment of the present disclosure.

FIG. 25 is a schematic structural view of the structure formed corresponding to the step S208 in the method for manufacturing the memory according to the embodiment of the present disclosure.

FIGS. 26 and 27 respectively show schematic diagrams of the structure formed corresponding to the step S208 in the method for manufacturing the memory from different perspectives according to the embodiment of the present disclosure.

FIG. 28 is a schematic structural view of the structure formed corresponding to step S210 in the method for manufacturing the memory according to the embodiment of the present disclosure.

FIG. 29 is a schematic structural view of the structure corresponding to the formation of the write transistor in the method for manufacturing the memory according to the embodiment of the present disclosure.

FIG. 30 is a schematic structural view of one kind of structure formed corresponding to step S2121 in the method for manufacturing the memory according to the embodiment of the present disclosure.

FIG. 31 is a schematic structural view of another kind of structure formed corresponding to step S2121 in the method for manufacturing the memory according to the embodiment of the present disclosure.

FIG. 32 is a schematic structural view of one kind of structure formed corresponding to step S2131 in the method for manufacturing the memory according to the embodiment of the present disclosure.

FIGS. 33 and 34 respectively show schematic diagrams of the structure formed corresponding to step S2132 in the method for manufacturing the memory from different perspectives according to the embodiment of the present disclosure.

FIG. 35 is a schematic structural view of the structure formed corresponding to step S2133 in the method for manufacturing the memory according to the embodiment of the present disclosure.

FIG. 36 is a schematic structural view of one kind of structure formed corresponding to step S214 in the method for manufacturing the memory according to the embodiment of the present disclosure.

FIG. 37 is a schematic structural view of another kind of structure formed corresponding to step S214 in the method for manufacturing the memory according to the embodiment of the present disclosure.

FIG. 38 is a schematic layout diagram of the storage unit and the second part of the gas channel on the horizontal plane in the memory according to the embodiment of the present disclosure.

FIG. 39 is a schematic structural view of one kind of structure formed corresponding to step S216 in the method for manufacturing the memory according to the embodiment of the present disclosure.

FIG. 40 is a schematic structural view after the second gas channel is formed corresponding to the method for manufacturing the memory in the second embodiment of the present disclosure.

FIG. 41 is a schematic structural view of the structure after the first gas channel is formed corresponding to the method for manufacturing the memory in the second embodiment of the present disclosure.

FIG. 42 is a schematic structural view of the structure after the second oxidized channel is formed corresponding to the method for manufacturing the memory in the second embodiment of the present disclosure.

FIG. 43 is a schematic structural view of the structure after the second filling body is formed corresponding to the method for manufacturing the memory in the second embodiment of the present disclosure.

FIG. 44 is a schematic structural view of the structure after the first oxidized channel is formed corresponding to the method for manufacturing the memory in second embodiment of the present disclosure.

FIG. 45 is a schematic structural view of the structure after the first filling body is formed corresponding to the method for manufacturing the memory in the second embodiment of the present disclosure.

FIG. 46 is a schematic structural view of the structure formed corresponding to step S308 in the method for manufacturing the memory according to the embodiment of the present disclosure.

FIG. 47 is a schematic structural view of the structure after the second filling body is formed by partially filling the second gas channel in the method for manufacturing the memory in the second embodiment of the present disclosure.

FIG. 48 is a schematic structural view of one kind of structure formed corresponding to step S406 in the method for manufacturing the memory according to the embodiment of the present disclosure.

FIG. 49 is a schematic structural view of another kind of structure formed corresponding to step S406 in the method for manufacturing the memory according to the embodiment of the present disclosure.

FIG. 50 is a schematic structural view of the structure formed corresponding to step S408 in the method for manufacturing the memory according to the embodiment of the present disclosure.

FIG. 51 is a schematic structural view of the structure after the first filling body is formed by partially filling the first gas channel in the method for manufacturing the memory in the second embodiment of the present disclosure.

### DETAILED DESCRIPTION OF THE EMBODIMENTS

The exemplary embodiments will now be described more comprehensively with reference to the accompanying drawings. However, the exemplary embodiments can be implemented in various forms and should not be construed as being limited to the examples set forth herein; rather, these embodiments are provided so that this application will be more comprehensive and complete, and will fully convey the concept of the exemplary embodiments to those skilled in the art.

In addition, the described features, structures, or characteristics may be combined in any suitable manner in one or more embodiments. In the following description, numerous specific details are provided to give a thorough understanding of the embodiments of the present application. However, those skilled in the art will recognize that the technical solutions of the present application can be practiced without one or more of the specific details, or other methods, components, devices, steps, etc. may be employed. In other cases, well-known methods, devices, implementations, or operations are not shown or described in detail to avoid obscuring various aspects of the present application.

The present application will be further described in detail below in conjunction with the accompanying drawings and specific embodiments. It should be noted here that the technical features involved in the various embodiments of the present application described below can be combined with each other as long as they do not conflict with each other. The embodiments described below with reference to the accompanying drawings are exemplary and are intended to explain the present application, and should not be construed as limiting the present application.

The present disclosure provides a method for manufacturing a memory, which may include a step S100, a step S102, and a step S104.

In step S100: providing a semiconductor substrate 10, as shown in FIG. 1; for example, the semiconductor substrate 10 may be a silicon (Si) substrate, but is not limited thereto, and may also be a germanium (Ge) substrate, etc., depending on the specific situation.

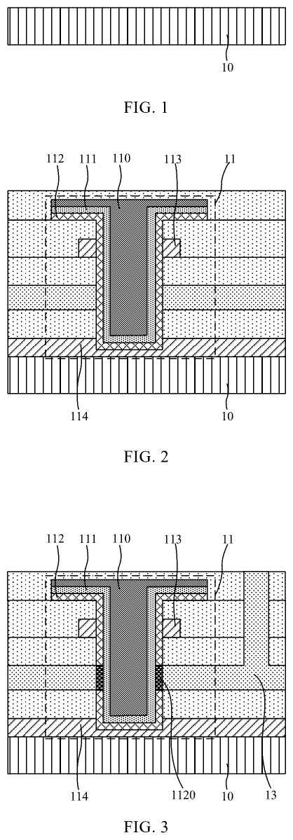

In step S102: preparing at least one storage unit on the semiconductor substrate 10. The storage unit may include at least one transistor 11, as shown in FIG. 2. The transistor 11 may be a three-dimensional structure. Specifically, each transistor 11 may include a gate electrode 110, a gate dielectric 111, a semiconductor channel 112, an upper electrode 113, and a lower electrode 114. The semiconductor channel 112 surrounds at least the outer peripheral side of the gate electrode 110, and the gate dielectric 111 is formed between the semiconductor channel 112 and the gate electrode 110 to prevent the semiconductor channel 112 from directly contacting the gate electrode 110. Both the upper electrode 113 and the lower electrode 114 are located outside the semiconductor channel 112 and are in contact with the semiconductor channel 112.

The lower electrode 114 is provided below the upper electrode 113 in an insulating manner, that is, the lower electrode 114 is closer to the semiconductor substrate 10 than the upper electrode 113. It should be noted that one of the upper electrode 113 and the lower electrode 114 is a source electrode, and the other is a drain electrode, and in the semiconductor channel 112, a part located between the upper electrode 113 and the lower electrode 114 can be defined as an effective semiconductor channel.

For example, there may be a plurality of storage units, which are provided on a horizontal plane to form a memory array structure. The memory array structure may have one layer or a plurality of layers stacked in the vertical direction. It should be understood that the horizontal plane mentioned in this embodiment refers to a plane parallel or approximately parallel to the semiconductor substrate 10, and the vertical direction refers to a direction perpendicular or approximately perpendicular to the semiconductor substrate 10.

In step S104: performing the oxidation treatment on the to-be-oxidized region of the effective semiconductor channel in at least one of the transistors 11 in the storage unit, to make the to-be-oxidized region formed into an oxidized channel 1120, as shown in FIG. 3; the to-be-oxidized region is at least a part of the effective semiconductor channel, and neither the upper electrode 113 nor the lower electrode 114 is in contact with the oxidized channel 1120.

In this embodiment, by performing the oxidation treatment only on the effective semiconductor channel located between the source and drain electrodes in the semiconductor channel 112, the region between the source and drain electrodes in the semiconductor channel 112 is formed into an oxidized channel 1120 with oxygen vacancies. While improving the control ability of the gate electrode 110 over the semiconductor channel 112 and increasing the on-current, since the regions in contact with the source and drain electrodes in the semiconductor channel 112 are not subjected to the oxidation treatment, the contact resistance between the source and drain electrodes and the semiconductor channel 112 can also be reduced.

It should be noted that the step S104 of this embodiment may be a sub-step of the step S102, but is not limited thereto. The Step S104 may also be a step performed after the preparation of the entire storage unit in the step S102 is completed. Specific descriptions may be made later according to the actual preparation situation, and no further elaboration will be given here.

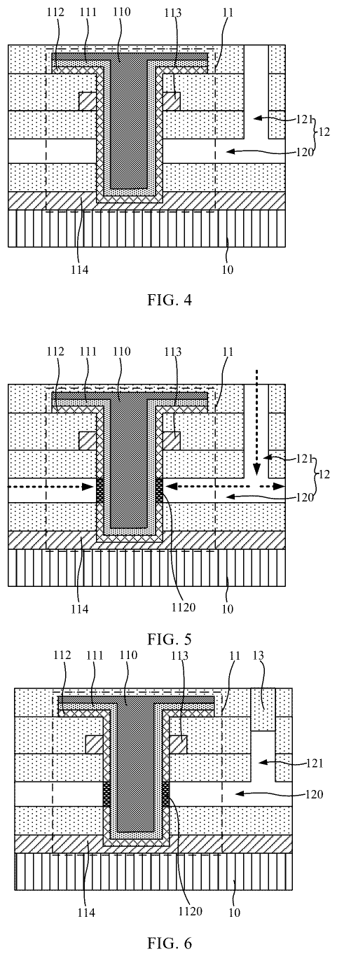

Before the oxidation treatment of the to-be-oxidized region in the semiconductor channel 112, the manufacturing method of this embodiment may further include preparing a gas channel 12, as shown in FIG. 4. The gas channel 12 may include a first part 120 surrounding the outer peripheral side of the to-be-oxidized region, and a second part 121 that is communicated with the first part 120 and extends vertically upwards. After the gas channel 12 is formed, the oxidization gas may be introduced from above the second part 121 to act on the to-be-oxidized region. That is, when the to-be-oxidized region in the semiconductor channel 112 is oxidized, as shown in FIG. 5, the oxidization gas may be introduced from the upper opening of the second part 121. This oxidization gas sequentially flows through the second part 121 and the first part 120 and acts on the to-be-oxidized region to oxidize the to-be-oxidized region into the oxidized channel 1120. The bold dotted line with an arrow in the gas channel 12 in FIG. 5 indicates the flow path of the oxidization gas.

In this embodiment, since the oxidized channel 1120 is formed in the effective semiconductor channel of the semiconductor channel 112, the electrical performance of the transistor 11 can be improved, and a threshold voltage that meets the requirements can be designed to achieve the control of the semiconductor channel 112. For example, the oxidization gas in this embodiment may at least include oxygen.

Since the first part 120 of the gas channel 12 is provided around the outer peripheral side of the to-be-oxidized region, the oxidized channel 1120 formed in this embodiment may also be provided in a ring shape, specifically surrounding the gate electrode 110 of the transistor 11.

In an optional embodiment, after the gas channel 12 is formed and before the target gas is introduced from above the second part 121, the manufacturing method of this embodiment may further include: introducing a repair agent from above the second part 121 to act on the to-be-oxidized region to perform a repair treatment on the surface of the to-be-oxidized region.

For example, when the semiconductor channel 112 is prepared from a metal oxide semiconductor material such as Indium Gallium Zinc Oxide (IGZO), the repair agent may at least include hydrogen, but is not limited thereto, and other types of repair agents may also be used, depending on the actual situation.

After the oxidized channel 1120 is formed, the manufacturing method of this embodiment may further include: filling the gas channel 12 with an insulating material to prevent the subsequent processing from affecting the oxidized channel 1120.

In some embodiments, the step of filling the gas channel 12 with an insulating material may include: completely filling the gas channel 12 with an insulating material to form a filling body 13 in the gas channel 12, as shown in FIG. 3. It should be understood that since the gas channel 12 is completely filled, both the first part 120 and the second part 121 of the gas channel 12 are filled with the insulating material, such design can ensure the structural stability. The upper surface of the filling body 13 is flush with the upper surface of the gas channel 12 to ensure the flatness of the upper surface of the structure, which is beneficial for other structural layers to be formed above it.

It should be understood that the upper surface mentioned in the present disclosure refers to the surface of an object away from the semiconductor substrate 10, and no further repetition will be made later.

In some other embodiments, the step of filling the gas channel 12 with an insulating material may include: partially or completely filling the second part 121 of the gas channel 12 with an insulating material to form a filling body 13 in the second part 121, as shown in FIG. 6, the upper surface of the filling body 13 is flush with the upper surface of the gas channel 12 to ensure the flatness of the upper surface of the structure, which is beneficial for other structural layers to be formed above it.

As shown in FIG. 6, the region of the gas channel 12 other than the region filled by the filling body 13 is a void, for example, if the filling body 13 only fills a part of the second part 121, then both the first part 120 of the gas channel 12 and the part of the second part 121 of the gas channel 12 that is not filled by the filling body 13 are void regions. If the filling body 13 completely fills the second part 121, then the first part 120 of the gas channel 12 is a void region. That is, when the second part 121 of the gas channel 12 is partially or completely filled with the insulating material to prevent the subsequent processing from affecting the oxidized channel, the first part 120 of the gas channel 12 can be formed into a void region, that is, there is a void between the upper electrode 113 and the lower electrode 114 of the transistor 11, as shown in FIG. 6, which can reduce the parasitic capacitance between the upper electrode 113 and the lower electrode 114 in the transistor 11.

It should be noted that if the second part 121 of the gas channel 12 is partially filled with the insulating material, the filled region should be the upper region of the second part 121, as shown in FIG. 6, so that the upper surface of the filling body 13 is flush with the upper surface of the gas channel 12, specifically, the filling body 13 can be formed by quickly sealing with the insulating material. The filling body 13 is formed in the upper region of the second part 121, and both the lower region of the second part 121 and the first part 120 are void regions.

The method for manufacturing the memory will be described in detail below in conjunction with the accompanying drawings and the specific structure of the storage unit. In the embodiment of the present disclosure, the storage unit may have a 2T0C structure, that is, the storage unit includes 2 transistors 11 and has no storage capacitor; one of the 2 transistors 11 of each storage unit is a read transistor 11R, and the other is a write transistor 11W.

For the convenience of subsequent description, in the embodiment of the present disclosure, the gate electrode 110, the gate dielectric 111, the semiconductor channel 112, the upper electrode 113, and the lower electrode 114 of the write transistor 11W are respectively defined as a first gate electrode 110W, a first gate dielectric 111W, a first semiconductor channel 112W, a first upper electrode 113W, and a first lower electrode 114W; and the gate electrode 110, the gate dielectric 111, the semiconductor channel 112, the upper electrode 113, and the lower electrode 114 of the read transistor 11R are respectively defined as a second gate electrode 110R, a second gate dielectric 111R, a second semiconductor channel 112R, a second upper electrode 113R, and a second lower electrode 114R.

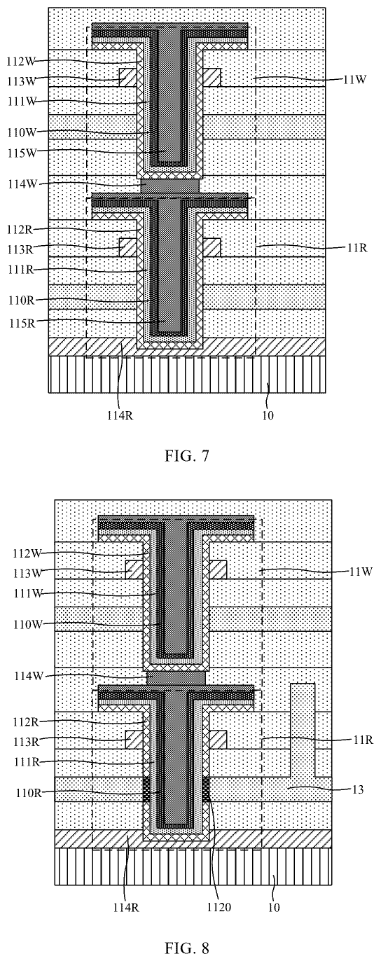

Referring to FIG. 7, in the storage unit: the write transistor 11W is located above the read transistor 11R, and the first lower electrode 114W of the write transistor 11W is conductively connected to the second gate electrode 110R of the read transistor 11R.

Performing the oxidation treatment on the to-be-oxidized region of the effective semiconductor channel in at least one of the transistors 11 in the storage unit, to make the to-be-oxidized region formed into the oxidized channel, mentioned in the foregoing step S104, may specifically include: performing the oxidation treatment on the to-be-oxidized region of the effective semiconductor channel of at least one of the write transistor 11W and the read transistor 11R. That is, the effective semiconductor channel of at least one of the write transistor 11W and the read transistor 11R includes the oxidized channel 1120.

In some embodiments, the method for manufacturing the memory of the present disclosure may include: performing the oxidation treatment on the to-be-oxidized region of the effective semiconductor channel of one of the write transistor 11W and the read transistor 11R to form the oxidized channel 1120; the gas channel 12 is prepared after the transistor 11 corresponding to the to-be-oxidized region is prepared, such that the inner side of the semiconductor channel 112 has structures such as the gate dielectric 111 and the gate electrode 110 to protect it, thereby reducing the damage to the semiconductor channel 112 during the preparation of the gas channel 12.

For example, referring to FIG. 8, the step of performing the oxidation treatment on the to-be-oxidized region of the transistor 11 in the storage unit in this embodiment may include: only performing the oxidation treatment on the to-be-oxidized region of the read transistor 11R in the storage unit, so that the effective semiconductor channel of the read transistor 11R includes the oxidized channel 1120. The gas channel 12 is prepared after the read transistor 11R is prepared, and the filling of the gas channel 12 is completed before the preparation of the write transistor 11W starts.

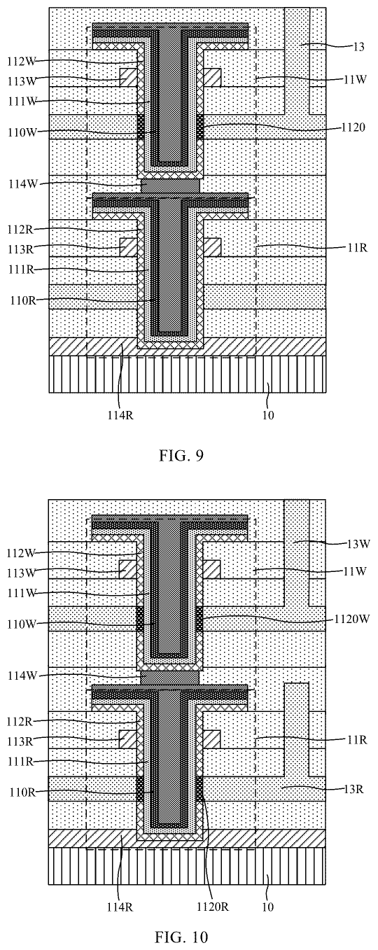

Alternatively, referring to FIG. 9, the step of performing the oxidation treatment on the to-be-oxidized region of the transistor 11 in the storage unit in this embodiment may include: only performing the oxidation treatment on the to-be-oxidized region of the write transistor 11W in the storage unit, so that the effective semiconductor channel of the write transistor 11W includes the oxidized channel 1120. The gas channel 12 is prepared after the write transistor 11W is prepared.

In some other embodiments, the manufacturing method of the present disclosure may include: performing the oxidation treatment on the to-be-oxidized regions of the effective semiconductor channels of both the write transistor 11W and the read transistor 11R, to make the to-be-oxidized regions of both the write transistor 11W and the read transistor 11R formed into the oxidized channels 1120.

For the convenience of the following description, the effective semiconductor channel of the first semiconductor channel 112W in the write transistor 11W can be defined as the first effective semiconductor channel, the to-be-oxidized region of the first effective semiconductor channel in the write transistor 11W can be defined as the first to-be-oxidized region, the effective semiconductor channel of the second semiconductor channel 112R in the read transistor 11R can be defined as the second effective semiconductor channel, and the to-be-oxidized region of the second effective semiconductor channel in the read transistor 11R can be defined as the second to-be-oxidized region.

Specifically, referring to FIG. 10, the aforementioned step of performing the oxidation treatment on the to-be-oxidized regions of the effective semiconductor channels of both the write transistor 11W and the read transistor 11R, to make the to-be-oxidized regions of both the write transistor 11W and the read transistor 11R formed into the oxidized channels 1120 may include: performing the oxidation treatment on the first to-be-oxidized region of the first effective semiconductor channel in the write transistor 11W, to make the first to-be-oxidized region formed into the first oxidized channel 1120W; and performing the oxidation treatment on the second to-be-oxidized region of the second effective semiconductor channel in the read transistor 11R, to make the second to-be-oxidized region formed into the second oxidized channel 1120R; performing the oxidation treatment on the to-be-oxidized regions of both the write transistor 11W and the read transistor 11R, to make both the write transistor 11W and the read transistor 11R formed with the oxidized channels 1120, so as to improve the electrical performance of the read transistor 11R and the write transistor 11W, and thus improve the storage performance of the storage unit.

The implementation manners of performing the oxidation treatment on the to-be-oxidized regions of the effective semiconductor channels of both the write transistor 11W and the read transistor 11R in this embodiment may include the following several types.

### The First Embodiment

In the implementation manner of the present disclosure, the first oxidized channel 1120W of the write transistor 11W and the second oxidized channel 1120R of the read transistor 11R may be formed simultaneously. That is, the first oxidized channel 1120W and the second oxidized channel 1120R may be formed in the same preparation step, which can improve the preparation efficiency and reduce the preparation cost.

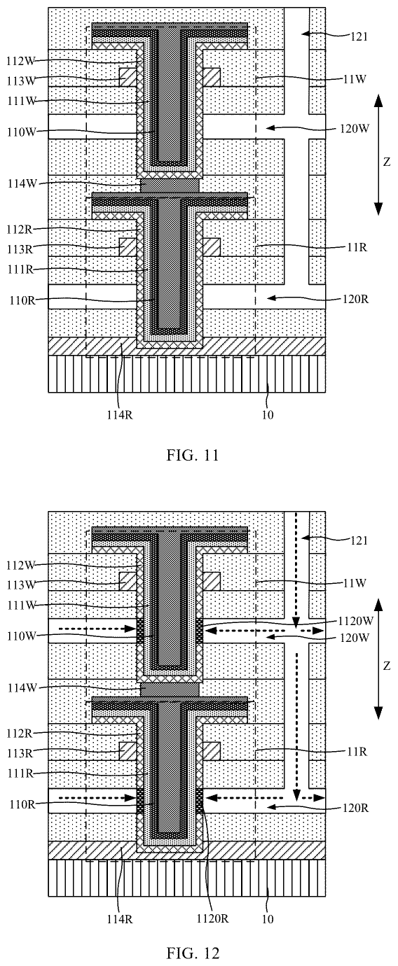

If the first oxidized channel 1120W and the second oxidized channel 1120R need to be formed simultaneously, the gas channel 12 can be prepared after the write transistor 11W is prepared. In this implementation manner, referring to FIG. 11, the first part 120 of the prepared gas channel 12 may include an upper first part 120W and a lower first part 120R. The upper first part 120W refers to the upper region of the first part 120 away from the semiconductor substrate 10, and the upper first part 120W surrounds the outer peripheral side of the first to-be-oxidized region. The lower first part 120R refers to the lower region of the first part 120 close to the semiconductor substrate 10, and the lower first part 120R surrounds the outer peripheral side of the second to-be-oxidized region.

It should be understood that, referring to FIG. 11, the upper first part 120W and the lower first part 120R of the gas channel 12 in this embodiment are provided at an interval in the vertical direction Z and are communicated with each other through the second part 121. Specifically, the second part 121 extends vertically upwards to the upper surface of the storage unit and communicates with the upper first part 120W and the lower first part 120R, so as to enable the oxidation gas introduced from above the second part 121 to act on the first to-be-oxidized region and the second to-be-oxidized region simultaneously for oxidation treatment. That is, referring to FIG. 12, the oxidation gas can enter the second part 121 through the air inlet of the second part 121, and a part of the oxidation gas can be shunted into the upper first part 120W to act on the first to-be-oxidized region for oxidation treatment, and another part of the oxidation gas can be shunted into the lower first part 120R to act on the second to-be-oxidized region for oxidation treatment, so that the first oxidized channel 1120W and the second oxidized channel 1120R are formed simultaneously. It should be noted that a bold dotted line with an arrow in FIG. 12 indicates the flow path of the oxidation gas.

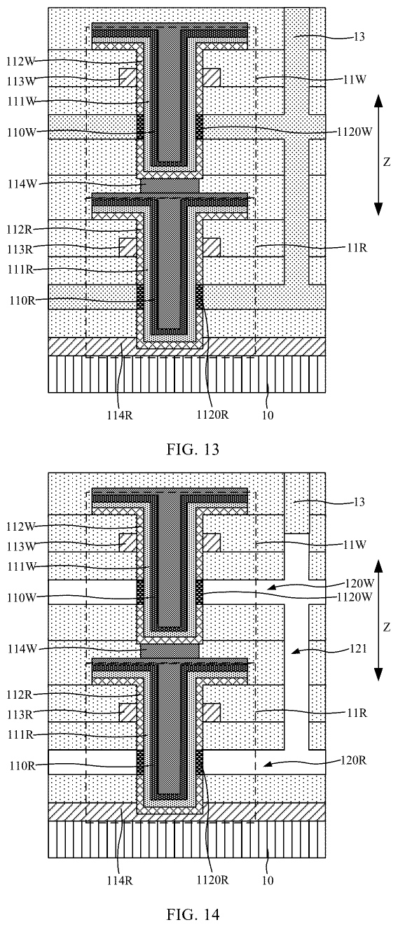

Exemplarily, after the first oxidized channel 1120W and the second oxidized channel 1120R are formed simultaneously, referring to FIG. 13, the gas channel 12 can be completely filled with the insulating material to form a filling body 13 in the gas channel 12.

In other words, the upper first part 120W, the lower first part 120R, and the second part 121 of the gas channel 12 are all filled with the filling body 13 made of the insulating material to ensure the structural stability of the storage unit. The upper surface of the filling body 13 can be flush with the upper surface of the storage unit to ensure the flatness of the upper surface of the memory array structure, which is beneficial for the preparation of subsequent structural layers.

It should be understood that, after the first oxidized channel 1120W and the second oxidized channel 1120R are formed simultaneously, it is not limited to filling the gas channel 12 in the aforementioned complete filling manner, and the gas channel 12 can also be filled in an incomplete filling manner. For example, the second part 121 can be divided into an upper main region and a lower communicating region along the vertical direction Z. The upper main region extends from the upper surface of the storage unit to the upper first part 120W and is communicated with the upper first part 120W, and the lower communicating region communicates with the upper first part 120W and the lower first part 120R. The insulating material can be filled in the upper main region by a quick sealing method to form the filling body 13 in the upper main region of the second part 121. Referring to FIG. 14, the upper surface of this filling body 13 is flush with the upper surface of the storage unit. It should be noted that the filling body 13 can completely fill the upper main region of the second part 121 or fill the upper half region of the upper main region.

If the gas channel 12 is filled in the aforementioned incomplete filling manner, referring to FIG. 14, both the upper first part 120W and the lower first part 120R are void regions that are not filled by the filling body 13, that is, there are voids between the first upper electrode 113W and the first lower electrode 114W and between the second upper electrode 113R and the second lower electrode 114R, which can reduce the parasitic capacitance between the first upper electrode 113W and the first lower electrode 114W and between the second upper electrode 113R and the second lower electrode 114R.

In a specific embodiment of the implementation manner of the present disclosure, the manufacturing method of the gas channel 12 including the upper first part 120W, the lower first part 120R, and the second part 121 may at least include a step S200, a step S202, a step S204, a step S206, a step S208, a step S210, a step S212, a step S214, and a step S216.

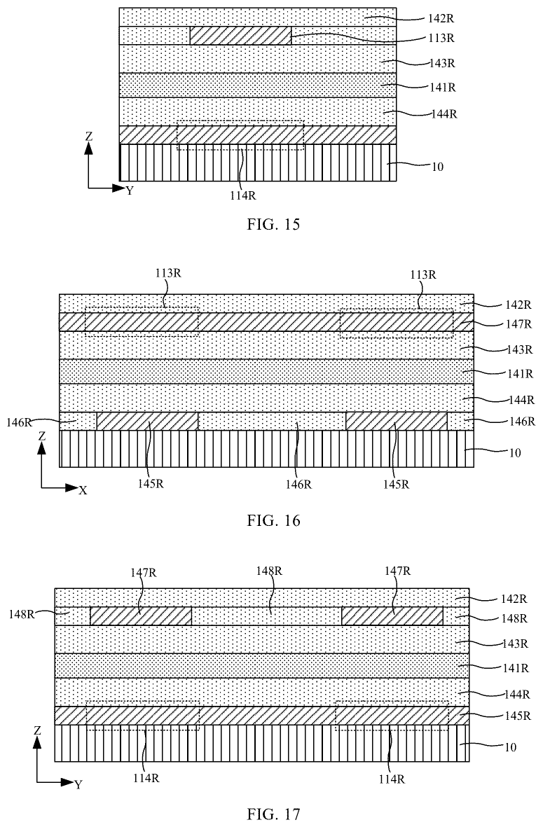

In step S200: forming a lower stacked film layer on the semiconductor substrate 10. Referring to FIG. 15, the lower stacked film layer at least includes a second lower electrode 114R, a lower sacrificial insulating film layer 141R, a second upper electrode 113R, and a lower isolation insulating film layer 142R that are stacked in sequence in the vertical direction Z. The material of the lower isolation insulating film layer 142R may be different from the materials of the lower sacrificial insulating film layer 141R and the subsequent upper sacrificial insulating film layer, so as to avoid the risk that the lower isolation insulating film layer 142R will be removed in the subsequent step of removing the upper sacrificial insulating film layer and the lower sacrificial insulating film layer 141R.

In some embodiments, referring to FIG. 15, the lower stacked film layer may further include a first lower interlayer dielectric layer 143R and a second lower interlayer dielectric layer 144R. The first lower interlayer dielectric layer 143R is formed between the second upper electrode 113R and the lower sacrificial insulating film layer 141R, and the second lower interlayer dielectric layer 144R is formed between the second lower electrode 114R and the lower sacrificial insulating film layer 141R.

The materials of the first lower interlayer dielectric layer 143R and the second lower interlayer dielectric layer 144R are different from the material of the lower sacrificial insulating film layer 141R, so as to avoid the risk that the first lower interlayer dielectric layer 143R and the second lower interlayer dielectric layer 144R will be removed in the subsequent step of removing the lower sacrificial insulating film layer 141R, thereby enabling the first lower interlayer dielectric layer 143R and the second lower interlayer dielectric layer 144R to protect the second upper electrode 113R and the second lower electrode 114R.

For example, the insulating materials of the first lower interlayer dielectric layer 143R, the second lower interlayer dielectric layer 144R, and the lower isolation insulating film layer 142R may be the same, for example, they all are silicon oxide, and the insulating material of the lower sacrificial insulating film layer 141R may be silicon nitride, silicon oxynitride, or silicon carbonitride, etc., but is not limited thereto, and specifically may be determined according to the actual situation.

In some embodiments of the present disclosure, the step S200 may specifically include a step S2001, a step S2002, a step S2003, and a step S2004.

In step S2001: forming a plurality of second lower signal lines 145R on the semiconductor substrate 10 that are provided at intervals in the first horizontal direction X and extend in the second horizontal direction Y, and forming a second lower isolation insulating portion 146R located between adjacent second lower signal lines 145R, as shown in combination with FIG. 16 and FIG. 17. In this embodiment, the second lower isolation insulating portion 146R can make adjacent second lower signal lines 145R insulated from each other; the second lower signal lines 145R can be formed on the semiconductor substrate 10 prior to the second lower isolation insulating portion 146R, but is not limited thereto, and the second lower isolation insulating portion 146R can also be formed first, and then the plurality of second lower signal lines 145R are formed.

It should be noted that the first horizontal direction X and the second horizontal direction Y mentioned at any position in the present disclosure are defined as directions parallel or approximately parallel to the semiconductor substrate 10, the first horizontal direction X intersects with the second horizontal direction Y; further, the first horizontal direction X and the second horizontal direction Y are perpendicular or approximately perpendicular to each other to reduce the design difficulty and save space.

In step S2002: forming a second lower interlayer dielectric layer 144R, a lower sacrificial insulating film layer 141R, and a first lower interlayer dielectric layer 143R that are stacked in sequence along the vertical direction Z on the upper surfaces (that is, the surfaces away from the semiconductor substrate 10) of the second lower signal lines 145R and the second lower isolation insulating portion 146R, as shown in combination with FIG. 16 and FIG. 17.

In step S2003: forming a plurality of second upper signal lines 147R on the first lower interlayer dielectric layer 143R that are provided at intervals in the second horizontal direction Y and extend in the first horizontal direction X, and forming a second upper isolation insulating portion 148R located between adjacent second upper signal lines 147R, as shown in combination with FIG. 16 and FIG. 17. In this embodiment, the second upper isolation insulating portion 148R can make adjacent second upper signal lines 147R insulated from each other; the second upper signal lines 147R can be formed on the first lower interlayer dielectric layer 143R prior to the second upper isolation insulating portion 148R, but is not limited thereto, and the second upper isolation insulating portion 148R can also be formed first, and then the plurality of second upper signal lines 147R are formed.

In the embodiment of the present disclosure, one of the second upper signal line 147R and the second lower signal line 145R is a read bit line, and the other is a read word line; as shown in combination with FIG. 16 and FIG. 17, there is an overlapping region in the orthographic projections of the second upper signal line 147R and the second lower signal line 145R on the semiconductor substrate 10. The portion of the second upper signal line 147R corresponding to the overlapping region can be defined as the second upper electrode 113R, and the portion of the second lower signal line 145R corresponding to the overlapping region can be defined as the second lower electrode 114R.

For example, the second upper signal line 147R and the second lower signal line 145R may include one or more of conductive materials such as titanium nitride (TiN), titanium (Ti), gold (Au), tungsten (W), molybdenum (Mo), indium tin oxide (ITO), aluminum (Al), copper (Cu), ruthenium (Ru), silver (Ag), and polysilicon, but are not limited thereto, and other conductive materials can also be used as long as it can ensure the performance of the second upper signal line 147R and the second lower signal line 145R.

In step S2004: forming a lower isolation insulating film layer 142R that covers entire surfaces of the second upper signal line 147R and the second upper isolation insulating portion 148R, as shown in combination with FIG. 16 and FIG. 17.

It should be noted that the lower isolation insulating film layer 142R may be integrally formed with the second upper isolation insulating portion 148R, but is not limited thereto, and it can also be prepared separately, depending on the specific situation.

In some other embodiments, the lower stacked film layer may not include the first lower interlayer dielectric layer 143R and the second lower interlayer dielectric layer 144R as shown in FIGS. 15 to 17, depending on the specific situation.

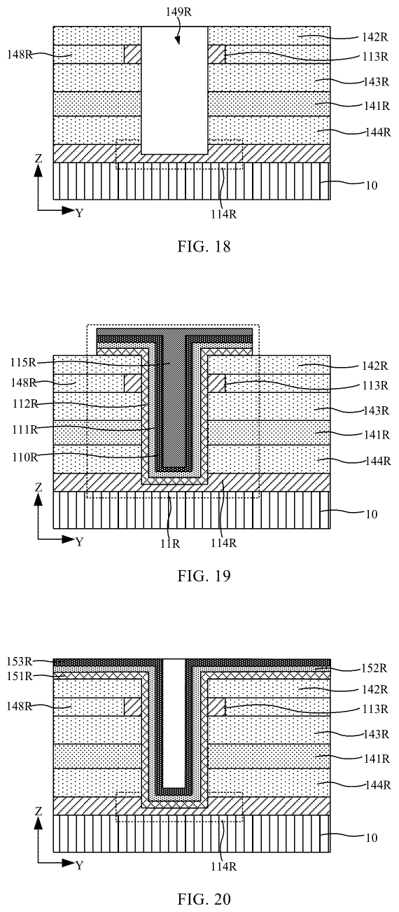

In step S202: forming a lower through hole 149R that penetrates at least the lower isolation insulating film layer 142R, the second upper electrode 113R, and the lower sacrificial insulating film layer 141R, as shown in FIG. 18. The second lower electrode 114R is exposed by the lower through hole 149R. It should be understood that since the second upper electrode 113R is a part of the second upper signal line 147R overlapping with the second lower signal line 145R, and the second lower electrode 114R is a part of the second lower signal line 145R overlapping with the second upper signal line 147R, the lower through hole 149R of this embodiment can be understood to be opened in the overlapping region of the second upper signal line 147R and the second lower signal line 145R.

When the lower stacked film layer also includes the first lower interlayer dielectric layer 143R and the second lower interlayer dielectric layer 144R, the lower through hole 149R may also penetrate the first lower interlayer dielectric layer 143R and the second lower interlayer dielectric layer 144R, as shown in FIG. 18.

For example, the lower surface of the lower through hole 149R may extend into the second lower electrode 114R, as shown in FIG. 18, such that the exposed area of the second lower electrode 114R can be larger, so as to increase the contact area with the semiconductor channel 112 subsequently. In addition, while ensuring the second lower electrode 114R is exposed, the etching precision can also be reduced, thus reducing the etching cost. However, it should be understood that the lower surface of the lower through hole 149R is not limited to extending into the second lower electrode 114R, or may also just extend to the upper surface of the second lower electrode 114R, or the lower through hole 149R may penetrate the second lower electrode 114R (that is, the lower surface of the lower through hole 149R is flush with or lower than the lower surface of the second lower electrode 114R), and so on.

In step S204: forming a second semiconductor channel 112R, a second gate dielectric 111R, and a second gate electrode 110R at the lower through hole 149R to form the read transistor 11R, as shown in FIG. 19. The second to-be-oxidized region of the second semiconductor channel 112R corresponds to the lower sacrificial insulating film layer 141R, that is, the second to-be-oxidized region of the second semiconductor channel 112R is located at the position surrounded by the lower sacrificial insulating film layer 141R.

It should be noted that when the lower stacked film layer includes the first lower interlayer dielectric layer 143R and the second lower interlayer dielectric layer 144R, after step S204 is executed, both the first lower interlayer dielectric layer 143R and the second lower interlayer dielectric layer 144R can be provided around the second effective semiconductor channel. Specifically, the first lower interlayer dielectric layer 143R can surround the region of the second effective semiconductor channel located above the second to-be-oxidized region, and the second lower interlayer dielectric layer 144R can surround the region of the second effective semiconductor channel located below the second to-be-oxidized region.

In some embodiments of the present disclosure, the step S204 may at least include a step S2041 and a step S2042.

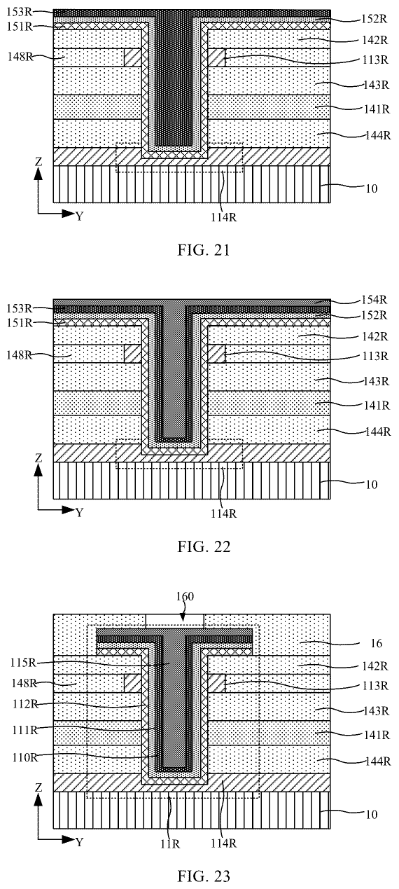

In step S2041: after the lower through hole 149R is formed, sequentially depositing a lower semiconductor film layer 151R, a lower gate dielectric film layer 152R, and a lower gate electrode film layer 153R on the lower stacked film layer, as shown in FIG. 20. The lower semiconductor film layer 151R, the lower gate dielectric film layer 152R, and the lower gate electrode film layer 153R all cover the entire surface of the lower stacked film layer. That is to say, the lower semiconductor film layer 151R, the lower gate dielectric film layer 152R, and the lower gate electrode film layer 153R can be deposited on the upper surface of the lower isolation insulating film layer 142R and inside the lower through hole 149R. The parts of the lower semiconductor film layer 151R and the lower gate dielectric film layer 152R located inside the lower through hole 149R may be U-shaped, and the part of the lower gate electrode film layer 153R located inside the lower through hole 149R may be U-shaped, as shown in FIG. 20; or the lower gate electrode film layer 153R may also fill the lower through hole 149R completely, as shown in FIG. 21.

For example, the material of the lower semiconductor film layer 151R may be a semiconductor material such as IGZO, but is not limited thereto, and other semiconductor materials may also be used. The material of the lower gate dielectric film layer 152R may be a high dielectric insulating material such as silicon oxide, but is not limited thereto, and low dielectric materials may also be used, and so on. The material of the lower gate electrode film layer 153R may be a conductive material with good gate control ability such as zinc oxide (ZnO), indium tin oxide (ITO), indium zinc oxide (IZO), etc., but is not limited thereto, and other conductive materials may also be used.

It should be noted that when the part of the lower gate electrode film layer 153R located inside the lower through hole 149R is U-shaped as shown in FIG. 20, the step S2041 may also include: after the lower gate electrode film layer 153R is deposited, depositing a lower conductive filling film layer 154R that covers the entire surface of the lower gate electrode film layer 153R, as shown in FIG. 22. The part of the lower conductive filling film layer 154R located inside the lower through hole 149R fills the lower through hole 149R. In this embodiment, the lower conductive filling film layer 154R can be made of a conductive material with good electrical conductivity and lower cost than that of the lower gate electrode film layer 153R.

In step S2042: etching off the parts of the lower semiconductor film layer 151R, the lower gate dielectric film layer 152R, and the lower gate electrode film layer 153R that exceed the target distance value from the hole boundary of the lower through hole 149R, so as to form the second semiconductor channel 112R, the second gate dielectric 111R, and the second gate electrode 110R at the lower through hole 149R, thereby forming the read transistor 11R, as shown in FIG. 19.

The target distance value mentioned in the step S2042 may be 0, that is, the parts of the lower semiconductor film layer 151R, the lower gate dielectric film layer 152R, and the lower gate electrode film layer 153R that exceed the boundary of the lower through hole 149R are all etched off, but it is not limited thereto. The target distance value mentioned in the step S2042 may also be greater than 0, but it should be less than half of the distance between adjacent lower through holes 149R, such that in addition to the parts located inside the lower through hole 149R, the second semiconductor channel 112R, the second gate dielectric 111R, and the second gate electrode 110R prepared also have parts extending in a direction away from the hole axis and overlapping on the upper surface of the lower isolation insulating film layer 142R, as shown in FIG. 19, such that when forming a plurality of read transistors 11R provided in an array, the etching difficulty can also be reduced, and the product quality can be ensured.

It should be understood that if the lower conductive filling film layer 154R that covers the entire surface of the lower gate electrode film layer 153R is included in the step S2041, then in the process of etching off the parts of the lower semiconductor film layer 151R, the lower gate dielectric film layer 152R, and the lower gate electrode film layer 153R that exceed the target distance value from the hole boundary in step S2042, it also includes etching off the parts of the lower conductive filling film layer 154R that exceed the target distance value from the hole boundary. The remaining un-etched part of the lower conductive filling film layer 154R is defined as the lower conductive filling portion 115R. The lower conductive filling portion 115R may be included in the read transistor 11R. One part of the lower conductive filling portion 115R fills the lower through hole 149R and is in contact with the second gate electrode 110R, and the other part overlaps on the upper surface of the second gate electrode 110R. It should be noted that the upper surface of the second gate electrode 110 mentioned in the present disclosure refers to the surface of the second gate electrode 110 farthest from the semiconductor substrate 10.

In step S206: forming an intermediate isolation insulating film layer 16 on the lower stacked film layer, as shown in FIG. 23. The intermediate isolation insulating film layer 16 covers at least the region of the upper surface of the lower isolation insulating film layer 142R that is not covered by the read transistor 11R, and the orthographic projection of at least part of the second gate electrode 110R on the semiconductor substrate 10 does not overlap with the orthographic projection of the intermediate isolation insulating film layer 16 on the semiconductor substrate 10. That is to say, at least part of the second gate electrode 110R is not blocked by the intermediate isolation insulating film layer 16, so as to be convenient for connection with the first lower electrode 114W of the write transistor 11W formed subsequently.

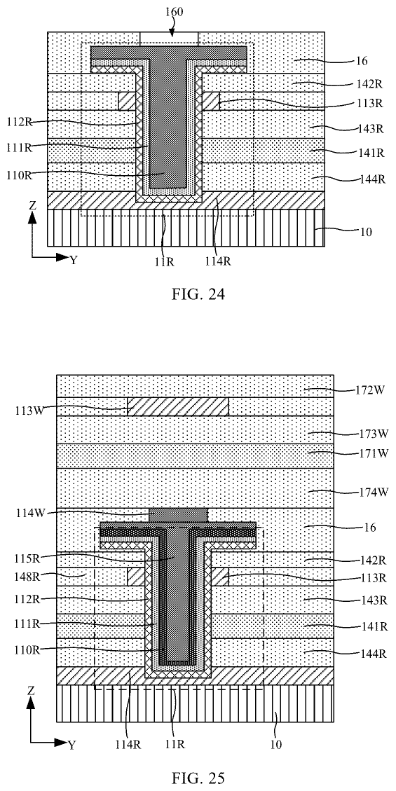

As shown in FIG. 23, if the part of the second gate electrode 110R located inside the lower through hole 149R is U-shaped, and the lower through hole 149R is filled with the lower conductive filling portion 115R, the upper surface of the intermediate isolation insulating film layer 16 may be higher than the upper surface of the lower conductive filling portion 115R, and the intermediate isolation insulating film layer 16 has a plurality of intermediate through holes 160 corresponding one-to-one to the lower conductive filling portions 115R. The intermediate through holes 160 expose at least part of the upper surface of the lower conductive filling portion 115R. As shown in FIG. 24, if the second gate electrode 110R fills the lower through hole 149R completely, the upper surface of the intermediate isolation insulating film layer 16 may be higher than the upper surface of the second gate electrode 110R, and the intermediate isolation insulating film layer 16 has a plurality of intermediate through holes 160 corresponding one-to-one to the second gate electrode 110R of the read transistor 11R. The intermediate through holes 160 expose at least part of the upper surface of the second gate electrode 110R.

In step S208: forming an upper stacked film layer. Referring to FIG. 25, the upper stacked film layer at least includes a first lower electrode 114W, an upper sacrificial insulating film layer 171W, a first upper electrode 113W, and an upper isolation insulating film layer 172W that are stacked in sequence along the vertical direction Z. The first lower electrode 114W is connected to the second gate electrode 110R, and the upper surface of the first lower electrode 114W is flush with the upper surface of the intermediate isolation insulating film layer 16.

For example, the material of the upper isolation insulating film layer 172W is different from the materials of the upper sacrificial insulating film layer 171W and the lower sacrificial insulating film layer 141R, so as to avoid the risk that the upper isolation insulating film layer 172W will be removed in the subsequent step of removing the upper sacrificial insulating film layer 171W and the lower sacrificial insulating film layer 141R.

In some embodiments, referring to FIG. 25, the upper stacked film layer may further include a first upper interlayer dielectric layer 173W and a second upper interlayer dielectric layer 174W. The first upper interlayer dielectric layer 173W is formed between the first upper electrode 113W and the upper sacrificial insulating film layer 171W, and the second upper interlayer dielectric layer 174W is formed between the intermediate isolation insulating film layer 16 and the upper sacrificial insulating film layer 171W.

For example, the materials of the first upper interlayer dielectric layer 173W and the second upper interlayer dielectric layer 174W are different from that of the upper sacrificial insulating film layer 171W and the lower sacrificial insulating film layer 141R, so as to avoid the risk that the first upper interlayer dielectric layer 173W and the second upper interlayer dielectric layer 174W will be removed in the subsequent step of removing the upper sacrificial insulating film layer 171W and the lower sacrificial insulating film layer 141R. Thus, the first upper interlayer dielectric layer 173W and the second upper interlayer dielectric layer 174W can be used to protect the first upper electrode 113W and the first lower electrode 114W.

For example, the insulating materials of the first upper interlayer dielectric layer 173W, the second upper interlayer dielectric layer 174W, the upper isolation insulating film layer 172W, the intermediate isolation insulating film layer 16, and the lower isolation insulating film layer 142R may be the same, for example, they can all be silicon oxide, and the insulating materials of the upper sacrificial insulating film layer 171W and the lower sacrificial insulating film layer 141R may also be the same. For example, they can both be silicon nitride, silicon oxynitride, or silicon carbonitride, etc. It should be understood that the insulating materials of each interlayer dielectric layer, the isolation insulating film layer, and the sacrificial insulating film layer are not limited to the aforementioned examples, and can also be other insulating materials, depending on the specific situation.

In some embodiments of the present disclosure, the step S208 may specifically include a step S2081, a step S2082, and a step S2083.

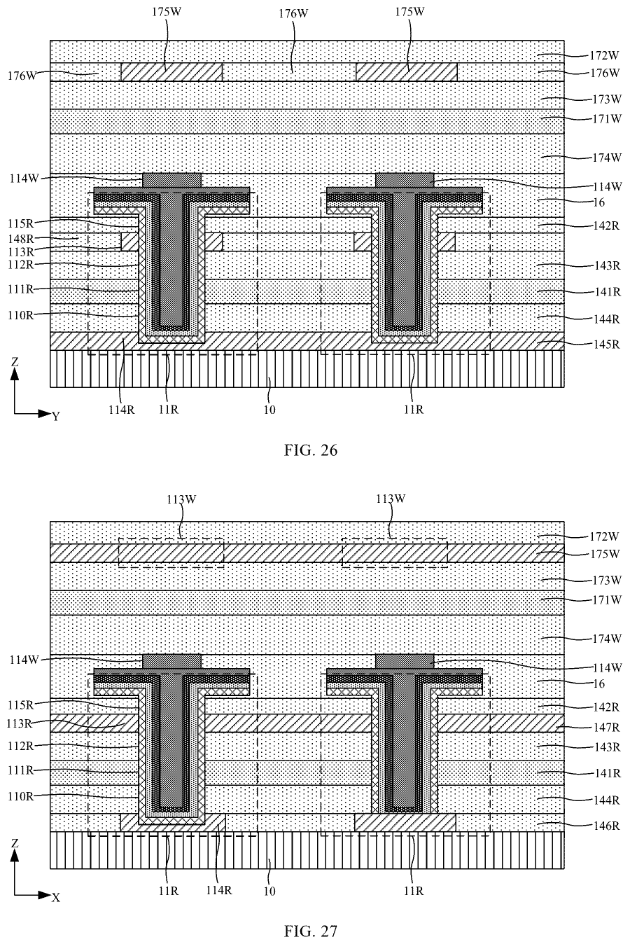

In step S2081: forming a plurality of first lower electrodes 114W provided in an array along the first horizontal direction X and the second horizontal direction Y. The first lower electrodes 114W are in one-to-one correspondence with the intermediate through holes 160. That is to say, each first lower electrode 114W is connected to a second gate electrode 110R, as shown in combination with FIG. 26 and FIG. 27.

It should be understood that if the second gate electrode 110R fills the lower through hole 149R completely, the lower surface of the first lower electrode 114W is in direct contact with the upper surface of the second gate electrode 110R to achieve the direct connection of the first lower electrode 114W and the second gate electrode 110R. The first lower electrode 114W and the second gate electrode 110R can be integrally formed, but it is not limited to this. The second gate electrode 110R and the first lower electrode 114W can also be prepared separately. That is, first the second gate electrode 110R is prepared, and then the first lower electrode 114W is prepared. In addition, the first lower electrode 114W and the second gate electrode 110R can be prepared with the same conductive material, but it is not limited to this, and they can also be prepared with different conductive materials, depending on the specific situation.

If the part of the second gate electrode 110R located inside the lower through hole 149R is U-shaped and the lower through hole 149R is filled with the lower conductive filling portion 115R completely, the lower surface of the first lower electrode 114W is in direct contact with the upper surface of the lower conductive filling portion 115R to achieve an indirect connection with the second electrode through the lower conductive filling portion 115R. The first lower electrode 114W can be integrally formed with the lower conductive filling portion 115R, but it is not limited to this. The lower conductive filling portion 115R and the first lower electrode 114W can also be prepared separately. That is, first the lower conductive filling portion 115R is prepared, and then the first lower electrode 114W is prepared. In addition, the first lower electrode 114W and the lower conductive filling portion 115R can be prepared with the same conductive material, but it is not limited to this, and they can also be prepared with different conductive materials, depending on the specific situation.

For example, if the first lower electrode 114W is integrally formed with the second gate electrode 110R or the first lower electrode 114W is integrally formed with the lower conductive filling portion 115R, the intermediate isolation insulating film layer 16 can be selected as a single layer structure integrally formed. For example, after the first lower electrode 114W is integrally formed with the second gate electrode 110R or the lower conductive filling portion 115R, the step S206 can specifically include: first forming an intermediate isolation insulating thin film that covers the entire surfaces of the lower isolation insulating film layer 142R, the second gate electrode 110R (or the lower conductive filling portion 115R), and the first lower electrode 114W, then entirely removing the part of the intermediate isolation insulating thin film that is higher than the upper surface of the first lower electrode 114W to form the intermediate isolation insulating film layer 16. The upper surface of the intermediate isolation insulating film layer 16 is flush with the upper surface of the first lower electrode 114W.

It should be understood that if the first lower electrode 114W is prepared separately from the second gate electrode 110R or the lower conductive filling portion 115R, the intermediate isolation insulating film layer 16 can also be a single layer structure integrally formed. For example, after the second gate electrode 110R or the lower conductive filling portion 115R is formed and before the first lower electrode 114W is formed, the step S206 can specifically include: first forming an intermediate isolation insulating thin film that covers the entire surfaces of the lower isolation insulating film layer 142R and the second gate electrode 110R (or the lower conductive filling portion 115R), then, removing the part of the intermediate isolation insulating thin film that is higher than the upper surface of the second gate electrode 110R (or the lower conductive filling portion 115R) to form the intermediate isolation insulating film layer 16 including the intermediate through holes 160, and then performing the step S2081, but it is not limited to this. If the first lower electrode 114W is prepared separately from the second gate electrode 110R or the lower conductive filling portion 115R, the intermediate isolation insulating film layer 16 can also be prepared in two layers. For example, after the second gate electrode 110R or the lower conductive filling portion 115R is formed, first a first intermediate insulating thin film that covers the entire surfaces of the lower isolation insulating film layer 142R and the second gate electrode 110R (or the lower conductive filling portion 115R) is formed. Then, the part of the first intermediate insulating thin film that is higher than the upper surface of the second gate electrode 110R (or the lower conductive filling portion 115R) as a whole is removed to form the first intermediate insulating film layer. The first intermediate insulating film layer covers the upper surface of the lower isolation insulating film layer 142R that is not covered by the read transistor 11R. Then, a second intermediate insulating thin film that covers the entire surfaces of the second intermediate insulating film layer and the second gate electrode 110R (or the lower conductive filling portion 115R) is formed. Then, the second intermediate insulating thin film is opened with a hole to form the second intermediate insulating film layer including the intermediate through holes. This second intermediate insulating film layer and the first intermediate insulating film layer form the intermediate isolation insulating film layer 16.

It should be noted that the preparation step of the second intermediate insulating film layer can be executed after the preparation step of the first lower electrode 114W or before the preparation step of the first lower electrode 114W, depending on the specific situation, and no more details will be given here.

In step S2082: forming a second upper interlayer dielectric layer 174W, an upper sacrificial insulating film layer 171W, and a first upper interlayer dielectric layer 173W stacked in sequence on the upper surfaces of the intermediate isolation insulating film layer 16 and the first lower electrode 114W, as shown in combination with FIG. 26 and FIG. 27.

In step S2083: forming a plurality of write bit lines 175W on the first upper interlayer dielectric layer 173W that are provided at intervals in the second horizontal direction Y and extend in the first horizontal direction X, and forming a first lower isolation insulating portion 176W located between adjacent write bit lines 175W, as shown in combination with FIG. 26 and FIG. 27. In this embodiment, the first lower isolation insulating portion 176W can insulate adjacent write bit lines 175W from each other. The write bit lines 175W can be formed on the first upper interlayer dielectric layer 173W prior to the first lower isolation insulating portion 176W, but it is not limited to this. The first lower isolation insulating portion 176W can also be formed first, and then a plurality of write bit lines 175W are formed.

In the embodiment of the present disclosure, the write bit line 175W may include a first upper electrode 113W, and there is an overlapping region in the orthographic projections of the first upper electrode 113W and the first lower electrode 114W on the semiconductor substrate 10.

In step S2084: forming an upper isolation insulating film layer 172W that covers entire surfaces of the write bit line 175W and the first lower isolation insulating portion 176W, as shown in combination with FIG. 26 and FIG. 27.

In some other embodiments, the upper stacked film layer may not include the first upper interlayer dielectric layer 173W and the second upper interlayer dielectric layer 174W, depending on the specific situation.

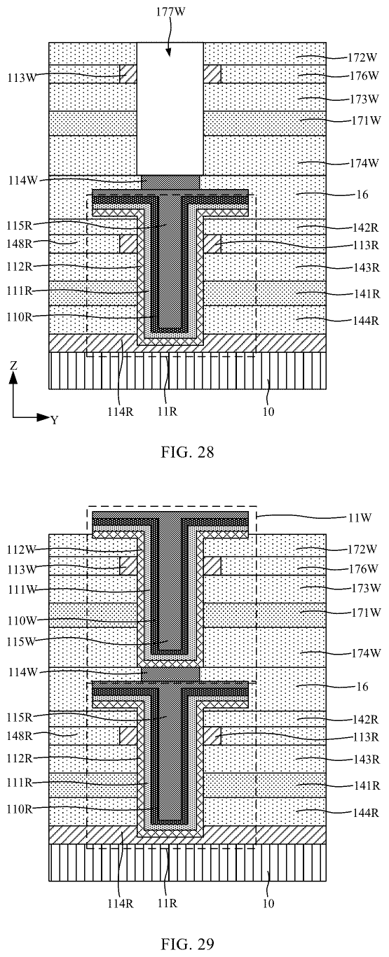

In step S210: forming an upper through hole 177W that penetrates at least the upper isolation insulating film layer 172W, the first upper electrode 113W, and the upper sacrificial insulating film layer 171W, as shown in FIG. 28. The first lower electrode 114W is exposed by the upper through hole 177W. That is to say, the upper through hole 177W can be opened at the region where the first upper electrode 113W and the first lower electrode 114W overlap correspondingly.

Exemplarily, the orthographic projections of the upper through hole 177W and the lower through hole 149R on the semiconductor substrate 10 may coincide, so that the write transistor 11W and the read transistor 11R of the storage unit coincide as much as possible in the vertical direction Z. While ensuring the performance of the storage unit, the horizontal area occupied by the storage unit can be reduced, so that more storage units can be provided per unit area, thereby increasing the storage density of the memory.

In some embodiments, when the upper stacked film layer also includes the first upper interlayer dielectric layer 173W and the second upper interlayer dielectric layer 174W, the upper through hole 177W may also penetrate the first upper interlayer dielectric layer 173W and the second upper interlayer dielectric layer 174W, as shown in FIG. 28.

For example, as shown in FIG. 28, the orthographic projection of the upper through hole 177W on the semiconductor substrate 10 may completely cover the orthographic projection of the first lower electrode 114W on the semiconductor substrate 10. At this time, the lower surface of the upper through hole 177W may just extend to the upper surface of the first lower electrode 114W to avoid the situation that poor etching occurs in subsequent continuous etching due to the different materials of the first lower electrode 114W and the intermediate isolation insulating film layer 16.

It should be understood that the orthographic projection of the upper through hole 177W on the semiconductor substrate 10 may be located within the orthographic projection of the first lower electrode 114W on the semiconductor substrate 10. At this time, the lower surface of the upper through hole 177W may extend into the first lower electrode 114W, so that the exposed area of the first lower electrode 114W can be larger, to increase the contact area with the semiconductor channel 112 subsequently. In addition, while ensuring the first lower electrode 114W is exposed, the etching precision can also be reduced, thus reducing the etching cost. However, it should be understood that the lower surface of the upper through hole 177W is not limited to extending into the first lower electrode 114W, and may also just extend to the upper surface of the first lower electrode 114W.

In step S212: forming a first semiconductor channel 112W, a first gate dielectric 111W, and a first gate electrode 110W in sequence at the upper through hole 177W to form the write transistor 11W, as shown in FIG. 29. The first to-be-oxidized region of the first semiconductor channel 112W corresponds to the upper sacrificial insulating film layer 171W, that is, the first to-be-oxidized region of the first semiconductor channel 112W is located at the position surrounded by the upper sacrificial insulating film layer 171W.

It should be noted that when the upper stacked film layer includes the first upper interlayer dielectric layer 173W and the second upper interlayer dielectric layer 174W, after the step S212 is executed, as shown in FIG. 29, both the first upper interlayer dielectric layer 173W and the second upper interlayer dielectric layer 174W can surround the first effective semiconductor channel. Specifically, the first upper interlayer dielectric layer 173W can surround the region of the first effective semiconductor channel located above the first to-be-oxidized region, and the second upper interlayer dielectric layer 174W can surround the region of the first effective semiconductor channel located below the first to-be-oxidized region.

In some embodiments of the present disclosure, the step S212 may at least include the step S2121 and the step S2122.

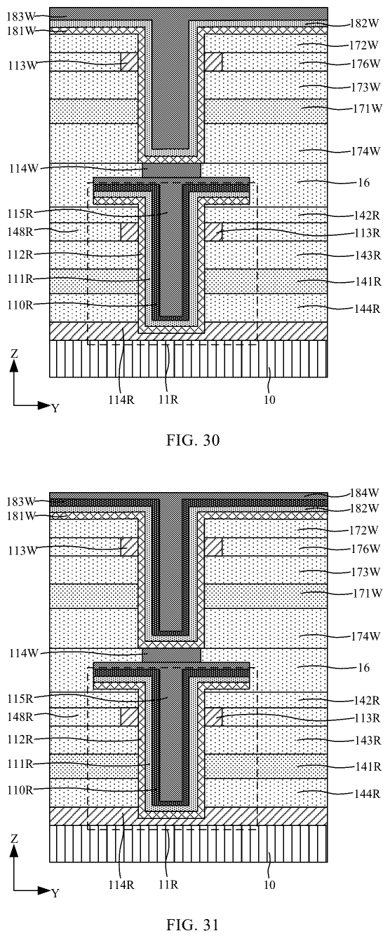

In step S2121: after the upper through hole 177W is formed, sequentially depositing an upper semiconductor thin film layer 181W, an upper gate dielectric thin film layer 182W, and an upper gate electrode thin film layer 183W on the upper stacked film layer, as shown in FIG. 30. The upper semiconductor thin film layer 181W, the upper gate dielectric thin film layer 182W, and the upper gate electrode thin film layer 183W all cover the entire surface of the upper stacked film layer. That is to say, the upper semiconductor thin film layer 181W, the upper gate dielectric thin film layer 182W, and the upper gate electrode thin film layer 183W can be deposited on the upper surface of the upper isolation insulating film layer 172W and inside the upper through hole 177W.

The parts of the upper semiconductor thin film layer 181W and the upper gate dielectric thin film layer 182W located inside the upper through hole 177W may be U-shaped, and the part of the upper gate electrode thin film layer 183W located inside the upper through hole 177W may be U-shaped, as shown in FIG. 31; or the upper gate electrode thin film layer 183W may fill the upper through hole 177W completely, as shown in FIG. 30.

For example, the material of the upper semiconductor thin film layer 181W may be a semiconductor material such as IGZO, but is not limited thereto, or may be other semiconductor materials. The material of the upper gate dielectric thin film layer 182W may be a high dielectric insulating material such as silicon oxide, but is not limited thereto, or may be low dielectric materials, and so on; the material of the upper gate electrode thin film layer 183W may be a conductive material with good gate control ability such as zinc oxide (ZnO), indium tin oxide (ITO), indium zinc oxide (IZO), etc., but is not limited thereto, and other conductive materials may also be used.

In step S2122: etching off the parts of the upper semiconductor thin film layer 181W, the upper gate dielectric thin film layer 182W, and the upper gate electrode thin film layer 183W that exceed the target distance value from the hole boundary of the upper through hole 177W, so as to form the first semiconductor channel 112W, the first gate dielectric 111W, and the first gate electrode 110W at the upper through hole 177W, thereby forming the write transistor 11W.

In the embodiment of the present disclosure, the target distance value mentioned in step S2122 may be 0, that is, the parts of the upper semiconductor thin film layer 181W, the upper gate dielectric thin film layer 182W, and the upper gate electrode thin film layer 183W that exceed the boundary of the upper through hole 177W are all etched off, but it is not limited thereto. The target distance value in the step S2122 may also be greater than 0, but it should be less than half of the distance between adjacent upper through holes 177W. In this way, in addition to the parts located inside the upper through hole 177W, the first semiconductor channel 112W, the first gate dielectric 111W, and the first gate electrode 110W prepared also have parts extending in a direction away from the hole axis and overlapping on the upper surface of the upper isolation insulating film layer 172W, as shown in FIG. 29. In this way, when forming a plurality of write transistors 11W provided in an array, the etching difficulty can also be reduced, and the product quality can be ensured.

When the part of the first gate electrode 110W located inside the upper through hole 177W is U-shaped, as shown in FIG. 29, the write transistor 11W of this embodiment may further include an upper conductive filling portion 115W that at least fills the upper through hole 177W completely. In this embodiment, the upper conductive filling portion 115W can be made of a conductive material with good electrical conductivity and lower cost than that of the first gate electrode 110W.

For example, the upper conductive filling portion 115W of this embodiment may be columnar, and the upper surface of the columnar upper conductive filling portion 115W may be flush with the upper surface of the first gate electrode 110W, but it is not limited to this. The upper conductive filling portion 115W may also be T-shaped, as shown in FIG. 29. While the T-shaped upper conductive filling portion 115W fills the upper through hole 177W completely, it can also cover the upper surface of the first gate electrode 110W. The upper surface of this first gate electrode 110W may be the surface of the first gate electrode 110W farthest from the semiconductor substrate 10.

In some embodiments, the manufacturing method of the upper conductive filling portion 115W may include: in the step S2121: after the upper gate electrode thin film layer 183W is deposited, as shown in FIG. 31, an upper conductive filling thin film layer 184W that covers the entire surface of the upper gate electrode thin film layer 183W is also deposited. Then, when the step S2112 is executed to etch off the parts of the upper semiconductor thin film layer 181W, the upper gate dielectric thin film layer 182W, and the upper gate electrode thin film layer 183W that exceed the target distance value from the hole boundary, the parts of the upper conductive filling thin film layer 184W that exceed the target distance value from the hole boundary are also etched off to form a T-shaped upper conductive filling portion. If the columnar upper conductive filling portion is desired to be formed, after the step S2112 is executed, the part of the T-shaped upper conductive filling portion that exceeds the upper surface of the first gate electrode 110W can be removed to form the columnar upper conductive filling portion.

It should be noted that the columnar upper conductive filling portion is not limited to being prepared in the aforementioned manner, and can also be prepared in the following manner. For example, after the step S2122 is executed to form the first gate electrode 110W, the first gate dielectric 111W, and the first semiconductor channel 112W of the write transistor 11W: first, the upper conductive filling thin film layer 184W is deposited. This upper conductive filling thin film layer 184W not only covers the entire surface of the structural layers below it, but also fills the upper through hole 177W completely. Then, the upper conductive filling thin film layer 184W is patterned to form a fully filled columnar upper conductive filling portion in each upper through hole 177W.

In some embodiments of the present disclosure, after the write transistor 11W is formed, the step S212 may further include: a step S2131, a step S2132, and a step S2133.

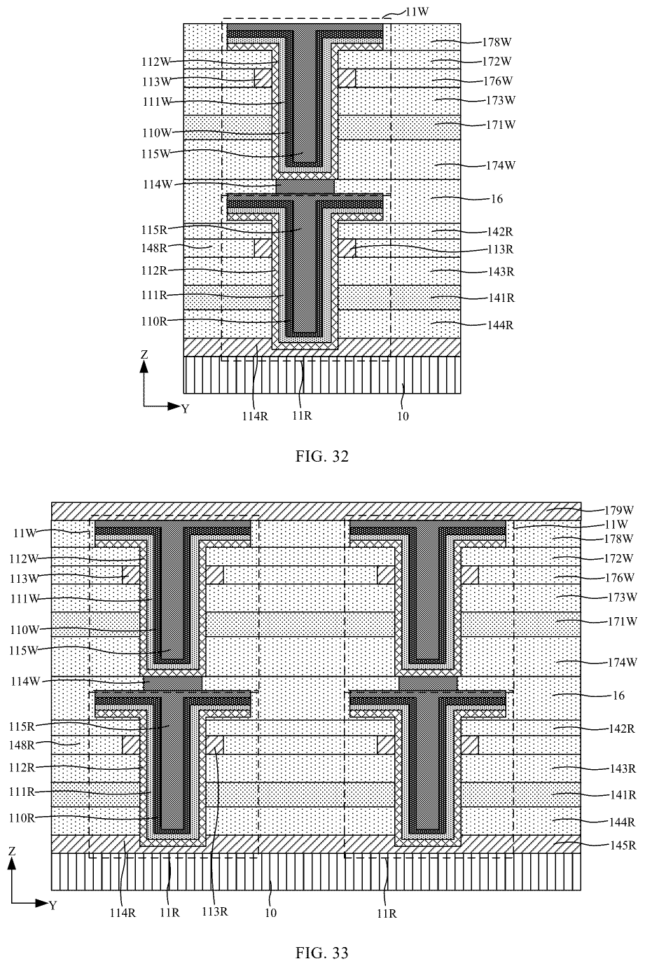

In step S2131: forming a filling isolation insulating portion 178W on the upper surface of the upper isolation insulating film layer 172W, as shown in FIG. 32. The filling isolation insulating portion 178W can cover the upper surface of the upper isolation insulating film layer 172W that is not covered by the write transistor 11W. It should be noted that if the first gate electrode 110W itself fills the upper through hole 177W completely or the prepared columnar upper conductive filling portion fills the upper through hole 177W completely, the upper surface of the filling isolation insulating portion 178W formed here may be flush with the upper surfaces of the first gate electrode 110W and the columnar upper conductive filling portion. If the prepared T-shaped upper conductive filling portion fills the upper through hole 177W completely, then the upper surface of the filling isolation insulating portion 178W formed here may be flush with the upper surface of the T-shaped upper conductive filling portion to ensure that the subsequent write word lines are formed on the flush surface.

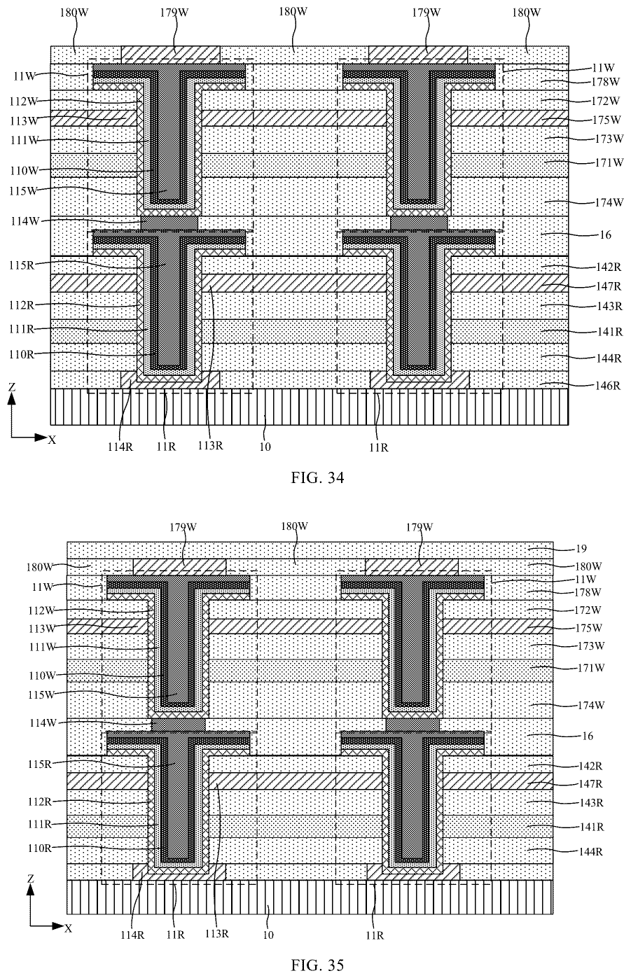

In step S2132: forming a plurality of write word lines 179W that are provided at intervals in the first horizontal direction X and extend in the second horizontal direction Y, and forming a first upper isolation insulating portion 180W located between adjacent write word lines 179W, as shown in combination with FIG. 33 and FIG. 34.

The write word line 179W can be connected to the first gate electrode 110W of a plurality of write transistors 11W that are provided at intervals in the second horizontal direction Y. If the first gate electrode 110W itself fills the upper through hole 177W completely, the write word line 179W can be in direct contact with the first gate electrode 110W to achieve a direct connection thereof. If the T-shaped upper conductive filling portion is used to fill the upper through hole 177W completely, the write word line 179W can be in direct contact with the upper surface of the T-shaped upper conductive filling portion to achieve an indirect connection with the first gate electrode 110W through the T-shaped upper conductive filling portion. If the columnar upper conductive filling portion is used to fill the upper through hole 177W completely, the write word line 179W can be in direct contact with both the first gate electrode 110W and the upper surface of the columnar upper conductive filling portion to achieve a connection among the three.

In step S2133: forming a capping insulating layer 19 that covers the entire surfaces of the write word line 179W and the filling isolation insulating portion 178W, as shown in FIG. 35, and the upper surface of the capping insulating layer 19 is a plane parallel or approximately parallel to the semiconductor substrate 10.

In this embodiment, adjacent write word lines 179W are insulated from each other through the first upper isolation insulating portion 180W. Specifically, the write word line 179W can be formed prior to the first upper isolation insulating portion 180W, but it is not limited to this. The first upper isolation insulating portion 180W can also be formed first, and then a plurality of write word lines 179W are formed.

In some embodiments, if the write word line 179W is formed first and the first upper isolation insulating portion 180W is formed later, the first upper isolation insulating portion 180W can be integrally formed with the capping insulating layer 19, but it is not limited to this. The first upper isolation insulating portion 180W can also be prepared separately from the capping insulating layer 19, that is, the first upper isolation insulating portion 180W is formed first, and then the capping insulating layer 19 is prepared.

In other embodiments, if the first upper isolation insulating portion 180W is formed first and the write word line 179W is formed later, the first upper isolation insulating portion 180W can be integrally formed with the filling isolation insulating portion 178W, but it is not limited to this. The first upper isolation insulating portion 180W can also be prepared separately from the filling isolation insulating portion 178W, that is, the filling isolation insulating portion 178W is formed first, and then the first upper isolation insulating portion 180W is prepared.

It should be understood that in the present disclosure, the write word line 179W is not limited to being formed after the first gate electrode 110W or the upper conductive filling portion 115W. It can also be integrally formed with the first gate electrode 110W or the upper conductive filling portion 115W, depending on the specific situation, and no more details will be given here. In addition, in the present disclosure, it is not limited that the write bit line 175W extends in the first horizontal direction X and the write word line 179W extends in the second horizontal direction Y. The write bit line 175W can also extend in the second horizontal direction Y and the write word line 179W can extend in the first horizontal direction X. As long as it is ensured that the extending directions of the write word line 179W and the write bit line 175W intersect.

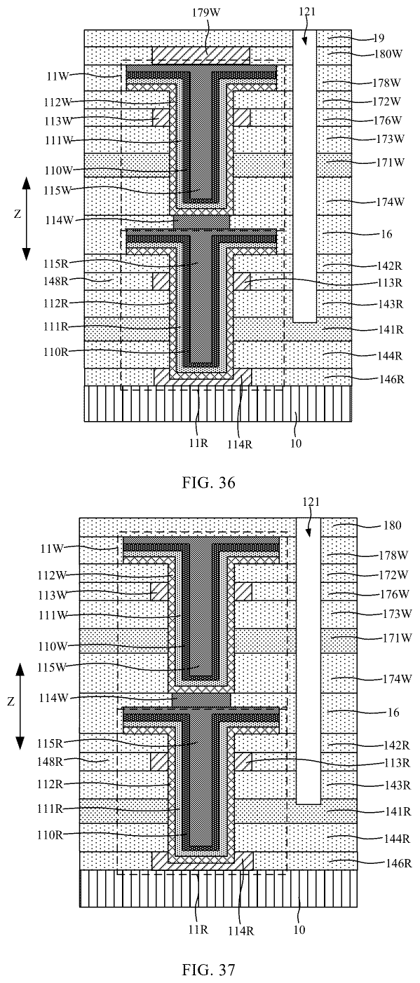

In step S214: forming a second portion 121 of the gas channel 12 after the write transistor 11W is formed. The orthographic projection of the second portion 121 on the semiconductor substrate 10 does not overlap with that of the lower through hole 149R and the upper through hole 177W on the semiconductor substrate 10, as shown in FIG. 36 and FIG. 37, the second portion 121 penetrates at least the upper isolation insulating film layer 172W, the upper sacrificial insulating film layer 171W, the intermediate isolation insulating film layer 16, and the lower isolation insulating film layer 142R, and exposes the lower sacrificial insulating film layer 141R. The second portion 121 of the gas channel 12 can extend vertically in the direction Z into the lower sacrificial insulating film layer 141R. In this way, while reducing the process difficulty, the exposed area of the lower sacrificial insulating film layer 141R can also be increased, so that the etching rate of the lower sacrificial insulating film layer 141R can be accelerated subsequently, but it is not limited to this. The second portion 121 of the gas channel 12 can also just extend to the upper surface of the lower sacrificial insulating film layer 141R, or penetrate the lower sacrificial insulating film layer 141R.

In some embodiments, as shown in FIG. 36, the second portion 121 of the gas channel 12 can be prepared after the capping insulating layer 19 is formed. At this time, the “upper surface of the storage unit” in the previously mentioned “the second portion 121 extends vertically upward to the upper surface of the storage unit” refers to the upper surface of the capping insulating layer 19. That is to say, after the capping insulating layer 19 is formed, the hole etching is performed vertically downward from the upper surface of the capping insulating layer 19 until the lower sacrificial insulating film layer 141R is etched. By preparing the second portion 121 of the gas channel 12 after the capping insulating layer 19, the capping insulating layer 19 can be used to protect the write transistor 11W and the write word line 179W, so as to avoid the situation of damaging the write transistor 11W and the write word line 179W during subsequent hole etching.

In some other embodiments, the second portion 121 of the gas channel 12 can also be prepared after the write transistor 11W is formed (or the upper conductive filling portion 115W is formed) and before the write word line 179W is formed. If the write transistor 11W is protected in this case, as shown in FIG. 37, after the write transistor 11W (or the upper conductive filling portion 115W is formed) is formed, a first upper isolation insulating thin film layer 180 that covers the entire surface of the write transistor 11W can be formed. At this time, the “upper surface of the storage unit” in the previously mentioned “the second portion 121 extends vertically upward to the upper surface of the storage unit” refers to the upper surface of the first upper isolation insulating thin film layer 180. Then, the hole etching is performed vertically downward from the upper surface of the first upper isolation insulating thin film layer 180 until the lower sacrificial insulating film layer 141R is etched. Then, the subsequent steps are executed. After the first oxidized channel 1120W and the second oxidized channel 1120R are formed and the second portion 121 of the gas channel 12 is partially or completely filled with the insulating material, the first upper isolation insulating thin film layer 180 is etched to form the first upper isolation insulating portion 180W. After that, the write word line 179W and the capping insulating layer 19 are formed, and so on.

In some embodiments, as shown in FIG. 36 and FIG. 37, when the lower stacked film layer includes the first lower interlayer dielectric layer 143R and the second lower interlayer dielectric layer 144R, and the upper stacked film layer includes the first upper interlayer dielectric layer 173W and the second upper interlayer dielectric layer 174W, the second portion 121 of the gas channel 12 can also penetrate the first upper interlayer dielectric layer 173W, the second upper interlayer dielectric layer 174W, and the first lower interlayer dielectric layer 143R.

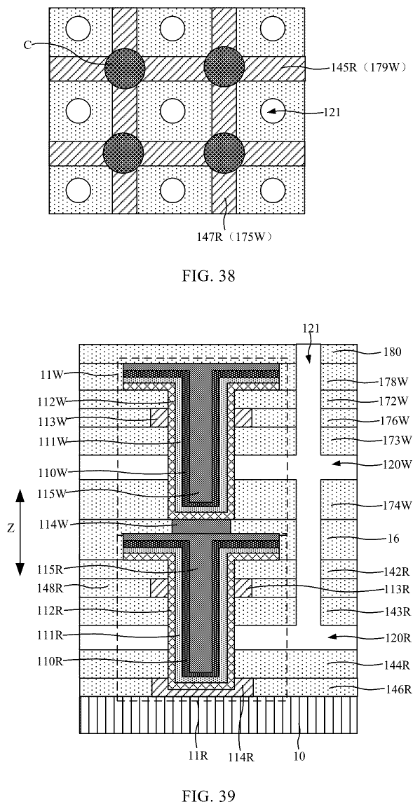

In some embodiments, as shown in FIG. 38, the orthographic projection of the second portion 121 of the gas channel 12 on the semiconductor substrate 10 also does not overlap with that of the write word line 179W, the write bit line 175W, the second lower signal line 145R, and the second upper signal line 147R on the semiconductor substrate 10, to ensure the performance of the write word line 179W, the write bit line 175W, the second lower signal line 145R, and the second upper signal line 147R. Since the orthographic projection of the second portion 121 of the gas channel 12 on the semiconductor substrate 10 does not overlap with that of the write word line 179W, the write bit line 175W, the second lower signal line 145R, and the second upper signal line 147R on the semiconductor substrate 10, the second portion 121 of the gas channel 12 can also penetrate the first upper isolation insulating portion 180W, the first lower isolation insulating portion 176W, and the second upper isolation insulating portion 148R in addition to the previously mentioned film layers, as shown in FIG. 36.

In some embodiments, as shown in FIG. 38, a plurality of second portions 121 of the gas channel 12 can be provided, and the plurality of second portions 121 can surround the outer periphery of each storage unit C. In this way, not only the etching rates of the upper sacrificial insulating film layer 171W and the lower sacrificial insulating film layer 141R can be accelerated, but also the etching uniformity can be ensured. I

In step S216, introducing an etchant into the second portion 121 to remove the upper sacrificial insulating film layer 171W and the lower sacrificial insulating film layer 141R, to form an upper first portion 120W surrounding the first to-be-oxidized region and a lower first portion 120R surrounding the second to-be-oxidized region, as shown in FIG. 39.

During the process of removing the upper sacrificial insulating film layer 171W and the lower sacrificial insulating film layer 141R with the etchant, the first lower interlayer dielectric layer 143R, the second lower interlayer dielectric layer 144R, the first upper interlayer dielectric layer 173W, and the second upper interlayer dielectric layer 174W are retained, that is, they are not etched or are etched very little by the etchant.

For example, the etchant in this embodiment can be a liquid, but it is not limited to this. It can also be a gas. When the insulating materials of the previously mentioned interlayer dielectric layers, the isolation insulating film layers, and isolation insulating portions are silicon oxide, and the insulating materials of the upper sacrificial insulating film layer 171W and the lower sacrificial insulating film layer 141R are silicon nitride, silicon oxynitride, or silicon carbonitride, etc., this embodiment can use chlorine gas or liquid phosphoric acid to completely etch off the upper sacrificial insulating film layer 171W and the lower sacrificial insulating film layer 141R, but it is not limited to this. In this embodiment, other etchants can also be used to etch off the upper sacrificial insulating film layer 171W and the lower sacrificial insulating film layer 141R. As long as it is ensured that the etchant can etch off the upper sacrificial insulating film layer 171W and the lower sacrificial insulating film layer 141R while having little or no impact on the previously mentioned interlayer dielectric layers, isolation insulating film layers, and isolation insulating portions, and can retain the previously mentioned interlayer dielectric layers, isolation insulating film layers, and isolation insulating portions.

### The Second Embodiment

In the embodiment of the present disclosure, the first oxidized channel 1120W of the write transistor 11W and the second oxidized channel 1120R of the read transistor 11R can be prepared separately. Specifically, the second oxidized channel 1120R of the read transistor 11R can be formed first, and then the first oxidized channel 1120W of the write transistor 11W can be formed, so as to ensure the quality of the first oxidized channel 1120W and the second oxidized channel 1120R.

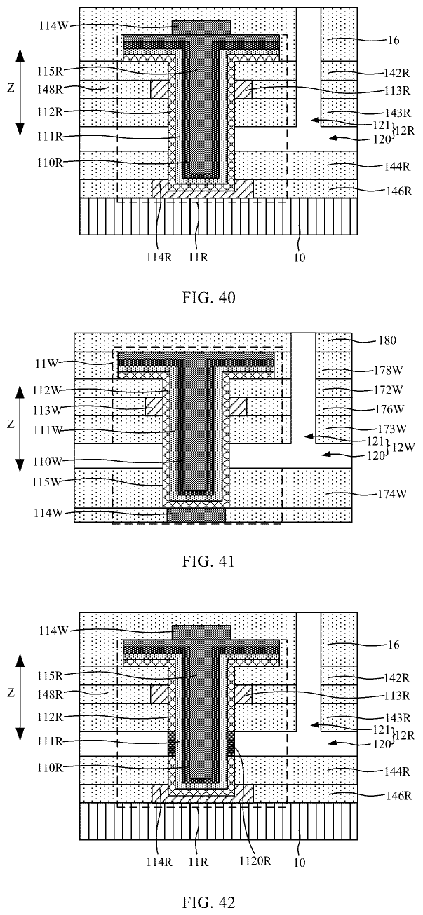

When the first oxidized channel 1120W of the write transistor 11W and the second oxidized channel 1120R of the read transistor 11R are formed separately, the previously mentioned gas channel 12 needs to include two channels manufactured successively, that is, the gas channel 12 can include a first gas channel 12W as shown in FIG. 41 and a second gas channel 12R as shown in FIG. 40. The first gas channel 12W and the second gas channel 12R are prepared separately, and the second gas channel 12R is prepared prior to the first gas channel 12W.

As shown in FIG. 40, the second gas channel 12R includes a first portion 120 surrounding the second to-be-oxidized region, and a second portion 121 that communicates with the first portion 120 of the second gas channel 12 and extends vertically upward to the upper surface of the read transistor 11R. As shown in FIG. 41, the first gas channel 12W includes the first portion 120 surrounding the first to-be-oxidized region, and the second portion 121 that communicates with the first portion 120 of the first gas channel 12W and extends vertically upward to the upper surface of the storage unit.

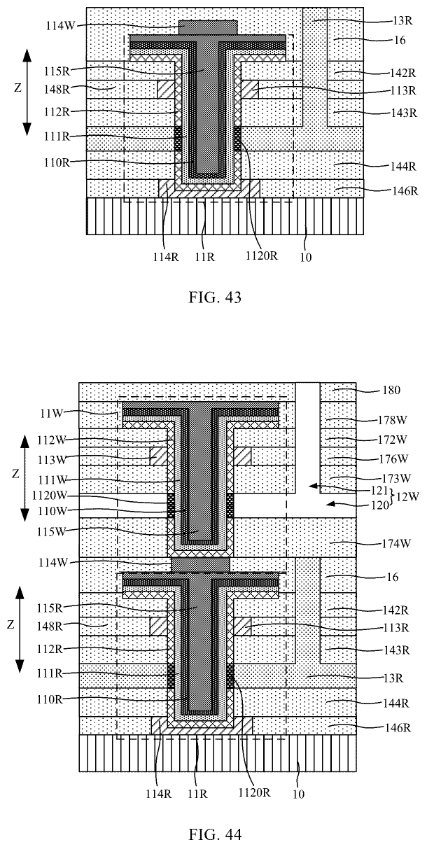

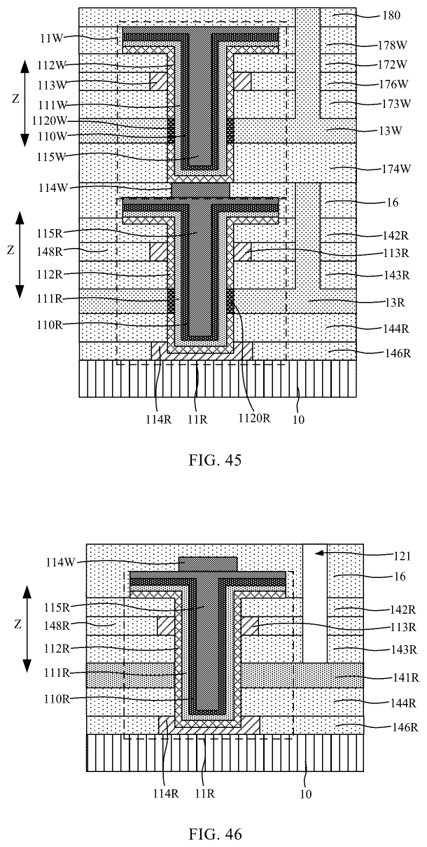

Based on this, the manufacturing method of this embodiment includes: first, performing the oxidation treatment on the second to-be-oxidized region of the second effective semiconductor channel of the read transistor 11R to form the second oxidized channel 1120R, as shown in FIG. 42; after the second oxidized channel 1120R is formed, filling the second gas channel 12R with an insulating material to form a second filling body 13R, as shown in FIG. 43. The upper surface of the second filling body 13R can be flush with the upper surface of the second gas channel 12R to ensure the flatness of the upper surface of the structural layer, which is beneficial to the preparation of the subsequent structural layer. Then, the oxidation treatment is performed on the first to-be-oxidized region of the first effective semiconductor channel of the write transistor 11W to form the first oxidized channel 1120W, as shown in FIG. 44. After the first oxidized channel 1120W is formed, the first gas channel 12W is filled with the insulating material to form a first filling body 13, as shown in FIG. 45. The upper surface of the first filling body 13 is flush with the upper surface of the first gas channel 12W to ensure the flatness of the upper surface of the memory array structure, which is beneficial to the preparation of the subsequent structural layer.

In a specific embodiment of the present disclosure, the manufacturing method of the first gas channel 12W can include a step S300, a step S302, a step S304, a step S306, a step S308, and a step S310. The step S300 can refer to the description at the previous step S200, the step S302 can refer to the description at the previous step S202, and the step S304 can refer to the description at the previous step S204. No more details will be given about the contents in the step S300, the step S302, and the step S304 here.

In step S306: forming an intermediate isolation insulating film layer 16 on the lower stacked film layer. The intermediate isolation insulating film layer 16 covers at least the upper surface of the lower isolation insulating film layer 142R that is not covered by the read transistor 11R. The intermediate isolation insulating film layer 16 formed in the step S306 can also completely cover the read transistor 11R to protect the read transistor 11R. It should be understood that when the lower conductive filling portion 115R is formed at the read transistor 11, the intermediate isolation insulating film layer 16 formed in the step S306 can also completely cover the lower conductive filling portion 115R while completely covering the read transistor 11 to protect both the read transistor 11 and the lower conductive filling portion 115R at the same time, but it is not limited to this. At least part of the second gate electrode 110R or the lower conductive filling portion 115R may not be blocked by the intermediate isolation insulating film layer 16, so as to facilitate the direct connection, indirect connection, or integral formation of the first lower electrode 114W and the second gate electrode 110R later, depending on the actual situation.

In step S308: forming the second portion 121 of the second gas channel 12R, as shown in FIG. 46. The orthographic projection of the second portion 121 of the second gas channel 12R on the semiconductor substrate 10 does not overlap with that of the lower through hole 149R on the semiconductor substrate 10, and the second portion 121 of the second gas channel 12R penetrates at least the intermediate isolation insulating film layer 16 and the lower isolation insulating film layer 142R, and exposes the lower sacrificial insulating film layer 141R.

The orthographic projection of the second portion 121 of the second gas channel 12R on the semiconductor substrate 10 also does not overlap with that of the read word line and the read bit line on the semiconductor substrate 10 to ensure the performance of the read word line and the read bit line. Since the orthographic projection of the second portion 121 of the second gas channel 12R on the semiconductor substrate 10 does not overlap with that of the read word line and the read bit line on the semiconductor substrate 10, the second portion 121 of the second gas channel 12R can also penetrate the second upper isolation insulating portion 148R in addition to the previously mentioned film layers. In addition, when the lower stacked film layer includes the first lower interlayer dielectric layer 143R and the second lower interlayer dielectric layer 144R, the second portion 121 of the second gas channel 12R can also penetrate the first lower interlayer dielectric layer 143R.

It should be noted that the previously mentioned second portion 121 of the second gas channel 12R extends vertically upward to the upper surface of the read transistor 11R. Here, the “upper surface of the read transistor 11R” can be understood as the upper surface of the structural layer where the read transistor 11R is located. The structural layer where the read transistor 11R is located includes the lower stacked film layer and the intermediate isolation insulating film layer 16 above the lower stacked film layer. Therefore, the “upper surface of the read transistor 11R” can be understood as the upper surface of the intermediate isolation insulating film layer 16. In other words, the second portion 121 of the second gas channel 12R can extend vertically downward from the upper surface of the intermediate isolation insulating film layer 16 to the lower sacrificial insulating film layer 141R, as shown in FIG. 41.

In some embodiments, the second portion 121 of the second gas channel 12R can extend vertically in the direction Z into the lower sacrificial insulating film layer 141R. In this way, while reducing the process difficulty, the exposed area of the lower sacrificial insulating film layer 141R can also be increased, so that the etching rate of the subsequent lower sacrificial insulating film layer 141R can be accelerated, but it is not limited to this. As shown in FIG. 46, the second portion 121 of the second gas channel 12R can also just extend to the upper surface of the lower sacrificial insulating film layer 141R, or penetrate the lower sacrificial insulating film layer 141R.

In some embodiments, there can be a plurality of second portions 121 of the second gas channel 12R, and the plurality of second portions 121 of the second gas channel 12R can surround the outer periphery of each read transistor 11R. In this way, not only the etching rate of the lower sacrificial insulating film layer 141R can be accelerated, but also the etching uniformity can be ensured.

In step S310, introducing an etchant into the second portion 121 of the second gas channel 12R to remove the lower sacrificial insulating film layer 141R, to form a first portion 120 of the second gas channel 12R surrounding the second to-be-oxidized region, as shown in FIG. 42. The limitation of the etchant can refer to the previous description, and no more details will be given here.

After the step S310 is executed, the oxidization gas is introduced through the second portion 121 of the second gas channel 12R. The oxidization gas acts on the second to-be-oxidized region through the first portion 120 of the second gas channel 12R to perform the oxidation treatment on the second to-be-oxidized region, to form the second oxidized channel 1120R. After the second oxidized channel 1120R is formed, the second gas channel 12R is filled with the insulating material to form the second filling body 13R, as shown in FIG. 43. The upper surface of the second filling body 13R can be flush with the upper surface of the intermediate isolation insulating film layer 16 to facilitate the formation of the subsequent write transistor 11W and its structural layer.

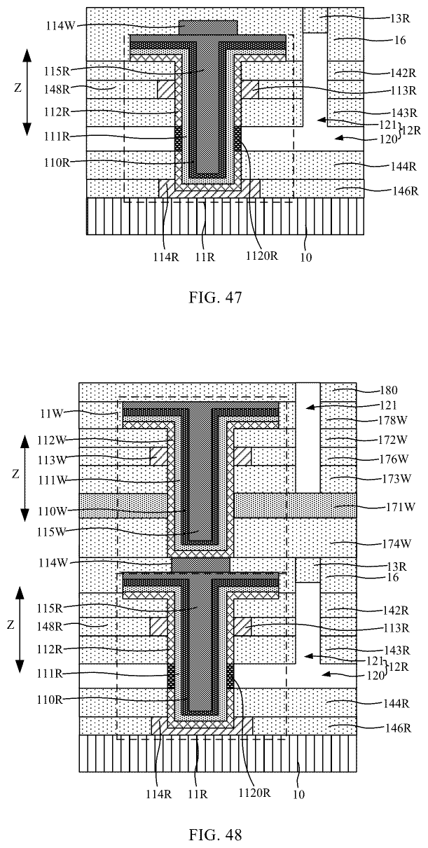

In some embodiments, when filling the second gas channel 12R with the insulating material, a complete filling method can be adopted. That is, as shown in FIG. 43, the formed second filling body 13R can completely fill the first portion 120 and the second portion 121 in the second gas channel 12R to ensure structural stability, but it is not limited to this. In other embodiments, as shown in FIG. 47, the insulating material can also be used to fill a part of the second gas channel 12R. That is, the formed second filling body 13R can partially or completely fill the second portion 121 of the second gas channel 12R. For example, the insulating material can be filled into the second portion 121 of the second gas channel 12R by a quick sealing method to form the second filling body 13R in the second portion 121 of the second gas channel 12R.

It should be understood that when the second filling body 13R partially or completely fills the second portion 121 of the second gas channel 12R, the regions of the second gas channel 12R other than the region filled by the second filling body 13R are void regions. Specifically, as shown in FIG. 47, at least the first portion 120 of the second gas channel 12R can be a void region not filled by the second filling body 13R. In this way, the parasitic capacitance between the second upper electrode 113R and the second lower electrode 114R in the read transistor 11R can be reduced.

In a specific embodiment of the present disclosure, the manufacturing method of the first gas channel 12W can include a step S400, a step S402, a step S404, a step S406, and a step S408. The step S400 can refer to the description at the previous the step S208, the step S402 can refer to the description at the previous step S210, and the step S404 can refer to the description at the previous step S212. No more details will be given about the contents in the step S400, the step S402, and the step S404 here.

In step S406: after the write transistor 11W is formed, forming a second portion 121 of the first gas channel 12W, as shown in FIG. 48. The orthographic projection of the second portion 121 of the first gas channel 12W on the semiconductor substrate 10 does not overlap with that of the upper through hole 177W on the semiconductor substrate 10, and the second portion 121 of the first gas channel 12W penetrates at least the upper isolation insulating film layer 172W and exposes the upper sacrificial insulating film layer 171W.

The second portion 121 of the first gas channel 12W can extend vertically in the direction Z into the upper sacrificial insulating film layer 171W. In this way, while reducing the process difficulty, the exposed area of the upper sacrificial insulating film layer 171W can also be increased, so that the etching rate of the subsequent upper sacrificial insulating film layer 171W can be accelerated, but it is not limited to this. As shown in FIG. 48, the second portion 121 of the first gas channel 12W can also just extend to the upper surface of the upper sacrificial insulating film, or penetrate the upper sacrificial insulating film.

In addition, there can be a plurality of second portions 121 of the first gas channel 12W, and a plurality of second portions 121 of the first gas channel 12W can surround the outer periphery of each write transistor 11W. In this way, not only the etching rate of the upper sacrificial insulating film layer 171W can be accelerated, but also the etching uniformity can be ensured.

In some embodiments, the manufacturing method of the first gas channel 12W can also include the step S4051, the step S4052, and the step S4053. The step S4051 can refer to the description at the previous step S2131, the step S4052 can refer to the description at the previous step S2132, and the step S4053 can refer to the description at the previous step S2133. No more details will be given about the contents in the step S4051, the step S4052, and the step S4053 here.

The orthographic projection of the second portion 121 of the first gas channel 12W on the semiconductor substrate 10 may not overlap with that of the write word line 179W and the write bit line 175W on the semiconductor substrate 10 to ensure the performance of the write word line 179W and the write bit line 175W. Since the orthographic projection of the second portion 121 of the first gas channel 12W on the semiconductor substrate 10 does not overlap with that of the write word line 179W and the write bit line 175W on the semiconductor substrate 10, the second portion 121 of the first gas channel 12W can also penetrate the first upper isolation insulating portion 180W and the first lower isolation insulating portion 176W in addition to the previously mentioned film layers. In addition, when the upper stacked film layer includes the first upper interlayer dielectric layer 173W and the second upper interlayer dielectric layer 174W, the second portion 121 of the first gas channel 12W can also penetrate the first upper interlayer dielectric layer 173W.

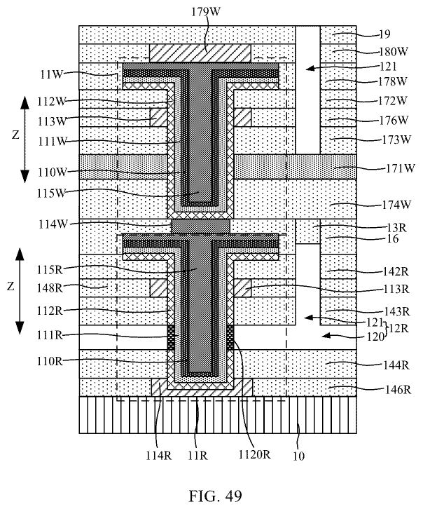

It should be noted that the previously mentioned second portion 121 of the first gas channel 12W extends vertically upward to the upper surface of the storage unit. Here, the “upper surface of the storage unit” can be understood as the upper surface of the capping insulating layer 19. That is to say, after the capping insulating layer 19 is formed, as shown in FIG. 49, the hole etching is performed vertically downward from the upper surface of the capping insulating layer 19 until the upper sacrificial insulating film layer 171W is etched. By preparing the second portion 121 of the first gas channel 12W after the capping insulating layer 19, the capping insulating layer 19 can be used to protect the write transistor 11W and the write word line 179W, so as to avoid the situation of damaging the write transistor 11W and the write word line 179W during subsequent hole etching, but it is not limited to this. The second portion 121 of the first gas channel 12W can also be prepared after the write transistor 11W (or the upper conductive filling portion 115W is formed) is formed and before the write word line 179W is formed. If the write transistor 11W is protected in this case, after the write transistor 11W (or the upper conductive filling portion 115W is formed) is formed, a first upper isolation insulating thin film layer 180 that covers the entire surface can be formed. At this time, the “upper surface of the storage unit” mentioned previously refers to the upper surface of the first upper isolation insulating thin film layer 180. Then, as shown in FIG. 48, the hole etching is performed vertically downward from the upper surface of the first upper isolation insulating thin film layer 180 until the upper sacrificial insulating film layer 171W is etched. Then, the subsequent steps are executed. After the first oxidized channel 1120W is formed and the first gas channel 12W is filled with an insulating material, the first upper isolation insulating thin film layer 180 is etched to form the first upper isolation insulating portion 180W. After that, the write word line 179W and the capping insulating layer 19 are formed, and so on.

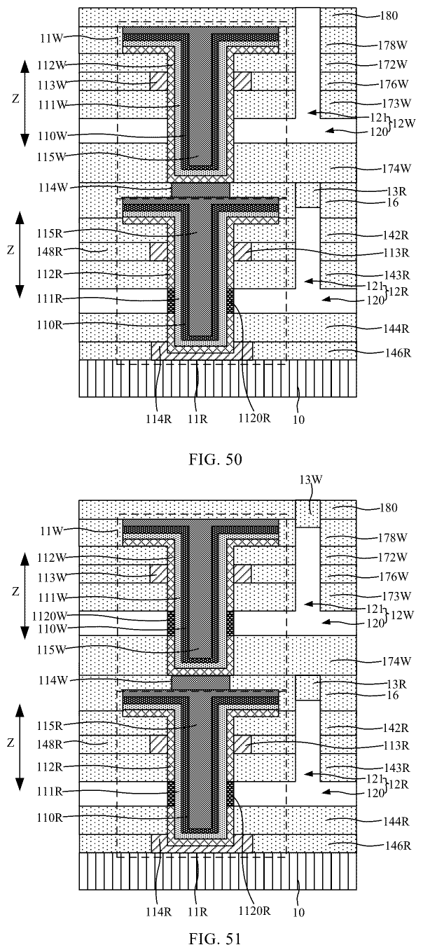

In step S408: introducing an etchant into the second portion 121 of the first gas channel 12W to remove the upper sacrificial insulating film layer 171W, and forming the first portion 120 of the first gas channel 12W surrounding the first to-be-oxidized region, as shown in FIG. 50. The limitation of the etchant can refer to the previous description, and no more details will be given here.

After step S408 is executed, the oxidization gas is introduced through the second portion 121 of the first gas channel 12W. The oxidization gas acts on the first to-be-oxidized region through the first portion 120 of the first gas channel 12W to perform the oxidation treatment on the first to-be-oxidized region, to form the first oxidized channel 1120W. After the first oxidized channel 1120W is formed, the first gas channel 12W is filled with the insulating material to form the first filling body 13W, as shown in FIG. 51. The upper surface of the first filling body 13W can be flush with the upper surface of the storage unit to facilitate the formation of the subsequent structural layer. In some embodiments, when filling the first gas channel 12W with the insulating material, a complete filling method can be adopted. That is, the formed first filling body 13W can completely fill the first portion 120 and the second portion 121 in the first gas channel 12W, as shown in FIG. 45, to ensure structural stability, but it is not limited to this. In other embodiments, the insulating material can also be used to fill a part of the first gas channel 12W. That is, as shown in FIG. 51, the formed first filling body 13W can partially or completely fill the second portion 121 of the first gas channel 12W. For example, the insulating material can be filled into the second portion 121 of the first gas channel 12W by a quick sealing method to form the first filling body 13W in the second portion 121 of the first gas channel 12W.

It should be understood that when the first filling body 13W partially or completely fills the second portion 121 of the first gas channel 12W, the regions of the first gas channel 12W other than the region filled by the first filling body 13W are void regions. Specifically, as shown in FIG. 51, at least the first portion 120 of the first gas channel 12W can be a void region not filled by the first filling body 13W. In this way, the parasitic capacitance between the first upper electrode 113W and the first lower electrode 114W in the write transistor 11W can be reduced.

The embodiment of the present disclosure also provides a memory, which includes a semiconductor substrate 10 and at least one storage unit. The storage unit is formed on the semiconductor substrate 10, and the storage unit includes at least one transistor 11. Each transistor 11 includes a gate 110, a gate dielectric 111, a semiconductor channel 112, an upper electrode 113, and a lower electrode 114. The semiconductor channel 112 surrounds at least the outer peripheral side of the gate 110. The gate dielectric 111 is formed between the semiconductor channel 112 and the gate 110. The upper electrode 113 and the lower electrode 114 are both located outside the semiconductor channel 112 and are in contact with the semiconductor channel 112. The lower electrode 114 is insulative and provided below the upper electrode 113, and one of the upper electrode 113 and the lower electrode 114 is a source electrode and the other is a drain electrode.

In the storage unit: a part of the effective semiconductor channel in at least one transistor 11 is oxidized to form an oxidized channel. The effective semiconductor channel is the part of the semiconductor channel 112 located between the upper electrode 113 and the lower electrode 114. Neither the upper electrode 113 nor the lower electrode 114 is in contact with the oxidized channel, as shown in FIG. 8, FIG. 9, or FIG. 10.

It should be understood that the memory in the embodiment of the present disclosure can be manufactured by the manufacturing method described in any of the previous embodiments, and no more details will be given here, but it is not limited to this. The memory in this embodiment can also be formed by other preparation methods.

In the embodiment of the present disclosure, there are a plurality of storage units, which are provided in a plane to form a memory array structure. Each storage unit includes 2 transistors 11, namely a read transistor 11R and a write transistor 11W. The write transistor 11W includes a first gate 110W, a first gate dielectric 111W, a first semiconductor channel 112W, a first upper electrode 113W, and a first lower electrode 114W. The read transistor 11R includes a second gate 110R, a second gate dielectric 111R, a second semiconductor channel 112R, a second upper electrode 113R, and a second lower electrode 114R. The write transistor 11W is located above the read transistor 11R, and the first lower electrode 114W is conductively connected to the second gate 110R. At least one of the write transistor 11W and the read transistor 11R has a part of the effective semiconductor channel 112 oxidized to form an oxidized channel 1120, as shown in FIG. 8, FIG. 9, or FIG. 10.

In the memory array structure: a plurality of storage units are provided in an array in the first horizontal direction X and the second horizontal direction Y. The first horizontal direction X intersects the second horizontal direction Y, as shown in FIG. 38. For example, the first horizontal direction X is perpendicular or approximately perpendicular to the second horizontal direction Y.

As shown in combination with FIG. 26, FIG. 27, FIG. 33, FIG. 34 and FIG. 38, the memory further includes a second lower signal line 145R, a second upper signal line 147R, a write word line 179W and a write bit line 175W. The second lower signal line 145R extends in the second horizontal direction Y, and the plurality of second lower signal lines 145R are provided at intervals in the first horizontal direction X. Each second lower signal line 145R is connected to the second lower electrode 114 of each read transistor 11R provided in a row in the second horizontal direction Y. The second upper signal line 147R extends in the first horizontal direction X, and the plurality of second upper signal lines 147R are provided at intervals in the second horizontal direction Y. The second upper signal line 147R is located on the side of the second lower signal line 145R away from the semiconductor substrate 10, and each second upper signal line 147R is connected to the second upper electrode 113R of each read transistor 11R provided in a row in the first horizontal direction X. One of the second upper signal line 147R and the second lower signal line 145R is a read word line, and the other is a read bit line. The write bit line 175W is formed on the side of the second upper signal line 147R away from the semiconductor substrate 10, and the write word line 179W is formed on the side of the write bit line 175W away from the semiconductor substrate 10. One of the write word line 179W and the write bit line 175W extends in the first horizontal direction X and the plurality of the one are provided at intervals in the second horizontal direction Y, and the other extends in the second horizontal direction Y and the plurality of of the other are provided at intervals in the first horizontal direction X. Each write bit line 175W is connected to the first upper electrode 113W of each write transistor 11W provided in a row in its extending direction, and each write word line 179W is connected to the first gate 110W of each write transistor 11W provided in a row in its extending direction.

In some embodiments, a part of the first effective semiconductor channel 112 of the write transistor 11W is oxidized to form the first oxidized channel 1120W. A first void region is formed between the first upper electrode 113W and the first lower electrode 114W, and the first void region is provided around the first oxidized channel 1120W, as shown in FIG. 14 and FIG. 51.

Further, as shown in FIG. 14 and FIG. 51, a first upper interlayer dielectric layer 173W is formed between the first upper electrode 113W and the first void region, and a second upper interlayer dielectric layer 174W is formed between the first lower electrode 114W and the first void region. Both the first upper interlayer dielectric layer 173W and the second upper interlayer dielectric layer 174W are provided around the first effective semiconductor channel 112 and do not contact the first oxidized channel 1120W.

In some other embodiments, a part of the first effective semiconductor channel 112 of the write transistor 11W is oxidized to form a first oxidized channel 1120W. A first insulating layer is formed between the first upper electrode 113W and the first lower electrode 114W. The first insulating layer is provided around the first oxidized channel 1120W and is seamlessly connected to the lower surface of the first upper electrode 113W and the upper surface of the first lower electrode 114W, as shown in FIG. 9, FIG. 10, FIG. 13 or FIG. 45.

For example, the first insulating layer may be a composite film layer including a first upper interlayer dielectric layer 173W, a second upper interlayer dielectric layer 174W and a first filling body 13W.

In some embodiments, a part of the second effective semiconductor channel 112 of the read transistor 11R is oxidized to form a second oxidized channel 1120R. A second void region is formed between the second upper electrode 113R and the second lower electrode 114R, and the second void region is provided around the second oxidized channel 1120R, as shown in FIG. 14 or FIG. 47 to FIG. 51.

Further, a first lower interlayer dielectric layer 143R is formed between the second upper electrode 113R and the second void region, and a second lower interlayer dielectric layer 144R is formed between the second lower electrode 114R and the second void region. Both the first lower interlayer dielectric layer 143R and the second lower interlayer dielectric layer 144R are provided around the second effective semiconductor channel 112 and do not contact the second oxidized channel 1120R.

In other embodiments, a part of the second effective semiconductor channel 112 of the read transistor 11R is oxidized to form a second oxidized channel 1120R. A second insulating layer is formed between the second upper electrode 113R and the second lower electrode 114R. The second insulating layer is provided around the second oxidized channel 1120R and is seamlessly connected to the lower surface of the second upper electrode 113R and the upper surface of the second lower electrode 114R, as shown in FIG. 8, FIG. 10, FIG. 13 or FIG. 44.

For example, the second insulating layer may be a composite film layer including a first lower interlayer dielectric layer 143R, a second lower interlayer dielectric layer 144R and a second filling body 13R.

In addition, terms such as “first” and “second” are only used for descriptive purposes and cannot be construed as indicating or implying relative importance or implicitly specifying the number of indicated technical features. Thus, a feature defined with “first” or “second” may explicitly or implicitly include one or more of such features. In the description of the present application, “a plurality of” means two or more, unless specifically defined otherwise.

In the description of this specification, descriptions referring to terms such as “some embodiments” and “exemplarily” mean that specific features, structures, materials or characteristics described in combination with the embodiment or example are included in at least one embodiment or example of the present application. In this specification, schematic representations of the above terms do not necessarily refer to the same embodiment or example. Moreover, the described specific features, structures, materials or characteristics may be combined in any suitable manner in any one or more embodiments or examples. In addition, those skilled in the art can combine and combine different embodiments or examples and features of different embodiments or examples described in this specification without conflict.

Although the embodiments of the present application are shown and described above, it can be understood that the above embodiments are exemplary and should not be construed as limiting the present application. Those skilled in the art can make changes, modifications, substitutions and variations to the above embodiments within the scope of the present application. Therefore, any changes or modifications made according to the claims and the specification of the present application shall fall within the scope covered by the patent of the present application.

What is claimed is:

1. A method for manufacturing a memory, comprising:
providing a semiconductor substrate;
preparing at least one storage unit on the semiconductor substrate;
wherein the storage unit comprises at least one transistor, and each transistor comprises a gate electrode, a gate dielectric, a semiconductor channel, an upper electrode and a lower electrode, wherein the semiconductor channel surrounds at least an outer peripheral side of the gate electrode, the gate dielectric is formed between the semiconductor channel and the gate electrode, the upper electrode and the lower electrode are located outside the semiconductor channel and are in contact with the semiconductor channel, and the lower electrode is provided below the upper electrode in an insulating manner, and one of the upper electrode and the lower electrode is a source electrode, and another one of the upper electrode and the lower electrode is a drain electrode;
performing an oxidation treatment on a to-be-oxidized region of an effective semiconductor channel in the at least one transistor in the storage unit, to make the to-be-oxidized region form an oxidized channel; and
wherein the to-be-oxidized region is at least a part of the effective semiconductor channel, and neither the upper electrode nor the lower electrode is in contact with the oxidized channel;
wherein the effective semiconductor channel is a part of the semiconductor channel located between the upper electrode and the lower electrode.

2. The method for manufacturing the memory according to claim 1, wherein before the oxidation treatment of the to-be-oxidized region, the method further comprises preparing a gas channel;
wherein the gas channel comprises a first part that is provided around an outer peripheral side of the to-be-oxidized region, and a second part that is communicated with the first part and extends vertically upwards, to make oxidation gas introduced from above the second part to act on the to-be-oxidized region.

3. The method for manufacturing the memory according to claim 2, wherein after the oxidized channel is formed, the method further comprises: filling the gas channel with an insulating material.

4. The method for manufacturing the memory according to claim 3, wherein filling the gas channel with the insulating material comprises: completely filling the gas channel with the insulating material to form a filling body in the gas channel, and an upper surface of the filling body is flush with an upper surface of the gas channel.

5. The method for manufacturing the memory according to claim 3, wherein filling the gas channel with the insulating material comprises: partially or completely filling the second part of the gas channel with the insulating material to form a filling body in the second part, and an upper surface of the filling body is flush with an upper surface of the gas channel;
wherein a region of the gas channel not filled by the filling body is a void region.

6. The method for manufacturing the memory according to claim 3, wherein a plurality of storage units are provided on a horizontal plane to form a memory array structure;
each storage unit comprises a read transistor and a write transistor;
the write transistor comprises a first gate electrode, a first gate dielectric, a first semiconductor channel, a first upper electrode and a first lower electrode;
the read transistor comprises a second gate electrode, a second gate dielectric, a second semiconductor channel, a second upper electrode and a second lower electrode; and
the write transistor is located above the read transistor, and the first lower electrode is conductively connected to the second gate electrode;
wherein the method comprises:
performing the oxidation treatment on the to-be-oxidized region of the effective semiconductor channel of at least one of the write transistor and the read transistor.

7. The method for manufacturing the memory according to claim 6, wherein the method comprises:
performing the oxidation treatment on the to-be-oxidized region of the effective semiconductor channel of one of the write transistor and the read transistor to form the oxidized channel;
wherein the gas channel is prepared after a transistor corresponding to the to-be-oxidized region is prepared.

8. The method for manufacturing the memory according to claim 6, wherein the method comprises:
performing the oxidation treatment on a first to-be-oxidized region of a first effective semiconductor channel in the write transistor, to make the first to-be-oxidized region form a first oxidized channel; and
performing the oxidation treatment on a second to-be-oxidized region of a second effective semiconductor channel in the read transistor, to make the second to-be-oxidized region form a second oxidized channel.

9. The method for manufacturing the memory according to claim 8, wherein the first oxidized channel and the second oxidized channel are formed simultaneously, and the gas channel is prepared after the write transistor is prepared;
wherein the first part of the gas channel comprises an upper first part surrounding an outer peripheral side of the first to-be-oxidized region and a lower first part surrounding an outer peripheral side of the second to-be-oxidized region; and
the upper first part and the lower first part are provided at intervals in a vertical direction, and the second part extends vertically upwards to an upper surface of the storage unit and communicates with the upper first part and the lower first part, to make the oxidation gas introduced from above the second part to act on the first to-be-oxidized region and the second to-be-oxidized region simultaneously for the oxidation treatment.

10. The method for manufacturing the memory according to claim 9, wherein a manufacturing method of the gas channel comprises:
forming a lower stacked film layer on the semiconductor substrate, wherein the lower stacked film layer at least comprises the second lower electrode, a lower sacrificial insulating film layer, the second upper electrode and a lower isolation insulating film layer stacked in sequence in the vertical direction;
forming a lower through hole that at least penetrates through the lower isolation insulating film layer, the second upper electrode and the lower sacrificial insulating film layer, wherein the second lower electrode is exposed by the lower through hole;
forming the second semiconductor channel, the second gate dielectric and the second gate electrode at the lower through hole to form the read transistor, wherein the second to-be-oxidized region of the second semiconductor channel is located at a position surrounded by the lower sacrificial insulating film layer;
forming an intermediate isolation insulating film layer on the lower stacked film layer, wherein the intermediate isolation insulating film layer at least covers a region of an upper surface of the lower isolation insulating film layer that is not covered by the read transistor, and orthographic projections of at least part of the second gate electrode and the intermediate isolation insulating film layer on the semiconductor substrate do not overlap;
form an upper stacked film layer, wherein the upper stacked film layer at least comprises the first lower electrode, an upper sacrificial insulating film layer, the first upper electrode and an upper isolation insulating film layer stacked in sequence in the vertical direction, and the first lower electrode is connected to the second gate electrode, and an upper surface of the first lower electrode is flush with an upper surface of the intermediate isolation insulating film layer;
forming an upper through hole that at least penetrates through the upper isolation insulating film layer, the first upper electrode and the upper sacrificial insulating film layer, wherein the first lower electrode is exposed by the upper through hole;
forming the first semiconductor channel, the first gate dielectric and the first gate electrode in sequence at the upper through hole to form the write transistor, wherein the first to-be-oxidized region of the first semiconductor channel is located at a position surrounded by the upper sacrificial insulating film layer;
forming the second part of the gas channel after the write transistor is formed, wherein an orthographic projection of the second part on the semiconductor substrate does not overlap with orthographic projections of the lower through hole and the upper through hole on the semiconductor substrate, and the second part at least penetrates through the upper isolation insulating film layer, the upper sacrificial insulating film layer, the intermediate isolation insulating film layer and the lower isolation insulating film layer, and exposes the lower sacrificial insulating film layer; and
introducing an etchant into the second part to remove the upper sacrificial insulating film layer and the lower sacrificial insulating film layer, to form an upper first part surrounding the first to-be-oxidized region and a lower first part surrounding the second to-be-oxidized region.

11. The method for manufacturing the memory according to claim 8, wherein the gas channel comprises a first gas channel and a second gas channel; the first gas channel comprises a first part that is provided around the first to-be-oxidized region, and a second part that is communicated with the first part of the first gas channel and extends vertically upwards to an upper surface of the storage unit;
wherein the second gas channel comprises a first part that is provided around the second to-be-oxidized region, and a second part that is communicated with the first part of the second gas channel and extends vertically upwards to an upper surface of the read transistor;
wherein the method comprises:
performing the oxidation treatment on the second to-be-oxidized region of the second effective semiconductor channel of the read transistor to form the second oxidized channel, and filling the second gas channel with the insulating material to form a second filling body after the second oxidized channel is formed, wherein an upper surface of the second filling body is flush with an upper surface of the second gas channel; and
performing the oxidation treatment on the first to-be-oxidized region of the first effective semiconductor channel of the write transistor to form the first oxidized channel, and filling the first gas channel with the insulating material to form a first filling body after the first oxidized channel is formed, wherein an upper surface of the first filling body is flush with an upper surface of the first gas channel.

12. The method for manufacturing the memory according to claim 11, wherein a manufacturing method of the first gas channel comprises:
forming a lower stacked film layer on the semiconductor substrate, wherein the lower stacked film layer at least comprises the second lower electrode, a lower sacrificial insulating film layer, the second upper electrode and a lower isolation insulating film layer stacked in sequence;
forming a lower through hole that at least penetrates through the lower isolation insulating film layer, the second upper electrode and the lower sacrificial insulating film layer, wherein the second lower electrode is exposed by the lower through hole;
forming the second semiconductor channel, the second gate dielectric and the second gate electrode at the lower through hole to form the read transistor, wherein the second to-be-oxidized region of the second semiconductor channel is located at a position surrounded by the lower sacrificial insulating film layer;
forming an intermediate isolation insulating film layer on the lower stacked film layer, wherein the intermediate isolation insulating film layer at least covers a region of an upper surface of the lower isolation insulating film layer that is not covered by the read transistor;
forming the second part of the second gas channel, wherein an orthographic projection of the second part of the second gas channel on the semiconductor substrate does not overlap with an orthographic projection of the lower through hole on the semiconductor substrate, and the second part of the second gas channel at least penetrates through the intermediate isolation insulating film layer and the lower isolation insulating film layer, and exposes the lower sacrificial insulating film layer; and
introducing an etchant into the second part of the second gas channel to remove the lower sacrificial insulating film layer, to form the first part of the second gas channel surrounding the second to-be-oxidized region.

13. The method for manufacturing the memory according to claim 12, wherein a manufacturing method of the first gas channel comprises:
forming an upper stacked film layer, wherein the upper stacked film layer at least comprises the first lower electrode, an upper sacrificial insulating film layer, the first upper electrode and an upper isolation insulating film layer stacked in sequence, wherein the first lower electrode is connected to the second gate electrode, and an upper surface of the first lower electrode is flush with an upper surface of the intermediate isolation insulating film layer;
forming an upper through hole that at least penetrates through the upper isolation insulating film layer, the first upper electrode and the upper sacrificial insulating film layer, wherein the first lower electrode is exposed by the upper through hole;
forming the first semiconductor channel, the first gate dielectric and the first gate electrode in sequence at the upper through hole to form the write transistor, wherein the first to-be-oxidized region of the first semiconductor channel is located at a position surrounded by the upper sacrificial insulating film layer;
forming the second part of the first gas channel after the write transistor is formed, wherein an orthographic projection of the second part of the first gas channel on the semiconductor substrate does not overlap with an orthographic projection of the upper through hole on the semiconductor substrate, and the second part of the first gas channel at least penetrates through the upper isolation insulating film layer and exposes the upper sacrificial insulating film layer; and
introducing the etchant into the second part of the first gas channel to remove the upper sacrificial insulating film layer, to form the first part of the first gas channel surrounding the first to-be-oxidized region.

14. The method for manufacturing the memory according to claim 10, wherein the lower stacked film layer further comprises a first interlayer dielectric layer and a second interlayer dielectric layer made of materials different from that of the lower sacrificial insulating film layer,
wherein the first interlayer dielectric layer is formed between the second upper electrode and the lower sacrificial insulating film layer and is provided around the second effective semiconductor channel, and the second interlayer dielectric layer is formed between the second lower electrode and the lower sacrificial insulating film layer and is provided around the second effective semiconductor channel;
wherein the upper stacked film layer further comprises a first interlayer dielectric layer and a second interlayer dielectric layer made of materials different from that of the upper sacrificial insulating film layer;
wherein the first interlayer dielectric layer is formed between the first upper electrode and the upper sacrificial insulating film layer and is provided around the first effective semiconductor channel, and the second interlayer dielectric layer is formed between the first lower electrode and the upper sacrificial insulating film layer and is provided around the first effective semiconductor channel;
wherein the first interlayer dielectric layer, the second interlayer dielectric layer, the first interlayer dielectric layer and the second interlayer dielectric layer are retained during using the etchant to remove the upper sacrificial insulating film layer and the lower sacrificial insulating film layer.

15. A memory, comprising:
a semiconductor substrate; and
at least one storage unit, formed on the semiconductor substrate;
wherein the storage unit comprises at least one transistor, and each transistor comprises a gate electrode, a gate dielectric, a semiconductor channel, an upper electrode and a lower electrode; the semiconductor channel surrounds at least an outer peripheral side of the gate electrode, and the gate dielectric is formed between the semiconductor channel and the gate electrode;
the upper electrode and the lower electrode are located outside the semiconductor channel and are in contact with the semiconductor channel, and the lower electrode is provided below the upper electrode in an insulating manner;
one of the upper electrode and the lower electrode is a source electrode, and another one of the upper electrode and the lower electrode is a drain electrode;
wherein in the storage unit: a part of an effective semiconductor channel in the at least one transistor is subjected to an oxidation treatment to form an oxidized channel; and
the effective semiconductor channel is a part of the semiconductor channel located between the upper electrode and the lower electrode, and neither the upper electrode nor the lower electrode is in contact with the oxidized channel.

16. The memory according to claim 15, wherein a plurality of storage units are provided on a horizontal plane to form a memory array structure;
each storage unit comprises a read transistor and a write transistor;
the write transistor comprises: a first gate electrode, a first gate dielectric, a first semiconductor channel, a first upper electrode and a first lower electrode;
the read transistor comprises: a second gate electrode, a second gate dielectric, a second semiconductor channel, a second upper electrode and a second lower electrode; and
the write transistor is located above the read transistor, and the first lower electrode is conductively connected to the second gate electrode;
wherein a part of the effective semiconductor channel of at least one of the write transistor and the read transistor is subjected to the oxidation treatment to form the oxidized channel.

17. The memory according to claim 16, wherein in the memory array structure: the plurality of storage units are provided in an array in a first horizontal direction and a second horizontal direction, and the first horizontal direction intersects with the second horizontal direction.

18. The memory according to claim 17, wherein the memory further comprises:
a plurality of second lower signal lines, provided at intervals in the first horizontal direction and extending in the second horizontal direction, wherein each second lower signal line is connected to the second lower electrode of each read transistor provided in the second horizontal direction in a row;
a plurality of second upper signal lines, provided at intervals in the second horizontal direction and extending in the first horizontal direction, wherein the second upper signal line is located on a side of the second lower signal line away from the semiconductor substrate, and each second upper signal line is connected to the second upper electrode of each read transistor provided in the first horizontal direction in the row, and one of the second upper signal line and the second lower signal line is a read word line, and another one of the second upper signal line and the second lower signal line is a read bit line; and
a write word line and a write bit line, wherein the write bit line is formed on a side of the second upper signal line away from the semiconductor substrate, and the write word line is formed on a side of the write bit line away from the semiconductor substrate,
wherein one of the write word line and the write bit line extends in the first horizontal direction and a plurality of write word lines are provided at intervals in the second horizontal direction, and another one of the write word line and the write bit line extends in the second horizontal direction and a plurality of write bit lines are provided at intervals in the first horizontal direction; and
each write bit line is connected to the first upper electrode of each write transistor provided in an extending direction of the write bit line in the row, and each write word line is connected to the first gate electrode of each write transistor provided in an extending direction of the write word line in the row.

19. The memory according to claim 16, wherein:
a partial region of a first effective semiconductor channel of the write transistor is subjected to the oxidation treatment to form a first oxidized channel, and a first void region is formed between the first upper electrode and the first lower electrode, and the first void region is provided around the first oxidized channel; and
a partial region of a second effective semiconductor channel of the read transistor is subjected to the oxidation treatment to form a second oxidized channel, and a second void region is formed between the second upper electrode and the second lower electrode, and the second void region is arranged around the second oxidized channel.

20. The memory according to claim 16, wherein:
a partial region of a first effective semiconductor channel of the write transistor is subjected to the oxidation treatment to form a first oxidized channel;
a first insulating layer is formed between the first upper electrode and the first lower electrode, and the first insulating layer is provided around the first oxidized channel and is seamlessly connected to a lower surface of the first upper electrode and an upper surface of the first lower electrode;
a partial region of a second effective semiconductor channel of the read transistor is subjected to the oxidation treatment to form a second oxidized channel; and
a second insulating layer is formed between the second upper electrode and the second lower electrode, and the second insulating layer is provided around the second oxidized channel and is seamlessly connected to a lower surface of the second upper electrode and an upper surface of the second lower electrode.
